(19) United States
(12) Patent Application Publication
(10) Pub. No.: US 2026/0215128 A1
(43) Pub. Date: Jul. 23, 2026

(54) DISPLAY DEVICE, ELECTRONIC DEVICE AND METHOD FOR MANUFACTURING DISPLAY DEVICE

(71) Applicant: Samsung Display Co., Ltd., Yongin-si (KR)

(72) Inventors: Ji Sun KIM, Yongin-si (KR); Sun Hwa LEE, Yongin-si (KR); Kwi Hyun KIM, Yongin-si (KR); Se Hyun LEE, Yongin-si (KR); Kyung Hoon CHUNG, Yongin-si (KR)

(21) Appl. No.: 19/375,695

(22) Filed: Oct. 31, 2025

(30) Foreign Application Priority Data
Jan. 22, 2025 (KR) 10-2025-0009349

(51) Int. Cl. H10K 59/80; H10H 29/01; H10H 29/32; H10H 29/37; H10H 29/49; H10H 29/80; H10K 59/12; H10K 59/121; H10K 59/122; H10K 59/131; H10K 102/10

(52) U.S. Cl. CPC H10K 59/80518; H10H 29/012; H10H 29/32; H10H 29/37; H10H 29/49; H10H 29/8323; H10H 29/8325; H10K 59/1201; H10K 59/1213; H10K 59/122; H10K 59/1315; H10K 59/80517; H10K 59/80524; H10K 2102/102; H10K 2102/103

(57) ABSTRACT

A display device includes: a pixel electrode and a common electrode spaced from each other on a substrate; and a light emitting element located on the pixel electrode and the common electrode, and electrically connected between the pixel electrode and the common electrode. The pixel electrode and the common electrode respectively include reflective layers overlapping with different parts of the light emitting element from each other.

### CROSS-REFERENCE TO RELATED APPLICATION

The present application claims priority to and the benefit of Korean Patent Application No. 10-2025-0009349, filed on January 22, 2025, in the Korean Intellectual Property Office, the entire disclosure of which is incorporated by reference herein.

### BACKGROUND

### 1. Field

Aspects of embodiments of the present disclosure relate to a display device, an electronic device, and a method for manufacturing the display device.

### 2. Description of the Related Art

With the advancement of information-oriented society, more and more demand is placed on display devices and electronic devices capable of displaying images in various ways. Accordingly, various kinds of display devices and electronic devices including pixels for displaying images are being developed. A display device may be provided alone, or may be included in an electronic device and used as a display screen of the electronic device.

### SUMMARY

Embodiments of the present disclosure may be directed to a display device, an electronic device, and a method for manufacturing the display device, in which a light efficiency may be improved and a manufacturing process may be simplified.

However, the aspects and features of the present disclosure are not restricted to the ones set forth herein. The above and other aspects and features of the present disclosure will become more apparent to those of ordinary skill in the art by referencing the description of some embodiments of the present disclosure below.

According to one or more embodiments of the present disclosure, a display device includes: a pixel electrode and a common electrode spaced from each other on a substrate; and a light emitting element located on the pixel electrode and the common electrode, and electrically connected between the pixel electrode and the common electrode. The pixel electrode and the common electrode respectively include reflective layers overlapping with different parts of the light emitting element from each other.

In an embodiment, the display device may further include a pixel defining layer surrounding around the light emitting element and spaced from the light emitting element.

In an embodiment, edge portions of the pixel electrode and the common electrode may be located on a side surface of the pixel defining layer.

In an embodiment, each of the pixel electrode and the common electrode may have a three-layered structure of indium-tin oxide (ITO), silver (Ag), and indium-tin oxide (ITO).

In an embodiment, the display device may further include: an adhesive layer covering a part of the pixel electrode and a part of the common electrode, and including a portion overlapping with the light emitting element from under the light emitting element; a first connection electrode located on the pixel electrode and the adhesive layer, and connecting a part of the light emitting element to the pixel electrode; and a second connection electrode located on the common electrode and the adhesive layer, and connecting another part of the light emitting element to the common electrode.

In an embodiment, the first connection electrode may be in contact with one side surface of the light emitting element on a part of the pixel electrode and the adhesive layer, and may be in contact with the pixel electrode on another part of the pixel electrode. The second connection electrode may be in contact with another side surface of the light emitting element on a part of the common electrode and the adhesive layer, and may be in contact with the common electrode on another part of the common electrode.

In an embodiment, the display device may further include a backplane layer located between the substrate and a pixel electrode layer including the pixel electrode and the common electrode, and the backplane layer may include a pixel circuit including a transistor, a connection pattern located below the pixel electrode and connecting the pixel electrode to the pixel circuit, and a power line electrically connected to the pixel circuit.

In an embodiment, the display device may further include a power bus line electrically connected to the common electrode, and including a first wiring layer extending from the common electrode.

In an embodiment, the power bus line may further include a second wiring layer located in the backplane layer, and electrically connected to the first wiring layer.

In an embodiment, the display device may further include a pad including a first pad layer located at a same layer as that of the second wiring layer, and including a same material as that of the second wiring layer.

In an embodiment, the display device may further include a first connection electrode connecting a part of the light emitting element to the pixel electrode, and a second connection electrode connecting another part of the light emitting element to the common electrode. The pad may further include a second pad layer located on the first pad layer, and including a same conductive material as a conductive material in the first connection electrode and the second connection electrode.

In an embodiment, the first connection electrode, the second connection electrode, and the second pad layer may include a transparent conductive oxide.

According to one or more embodiments of the present disclosure, a method for manufacturing a display device, includes: forming a pixel electrode and a common electrode on a substrate; forming an adhesive layer covering a part of the pixel electrode and a part of the common electrode; arranging a light emitting element on the adhesive layer; and forming a first connection electrode connecting a part of the light emitting element to the pixel electrode on the pixel electrode and the adhesive layer, and forming a second connection electrode connecting another part of the light emitting element to the common electrode on the common electrode and the adhesive layer. Each of the pixel electrode and the common electrode is formed as a reflective electrode including a reflective layer.

In an embodiment, the method may further include: before the forming of the pixel electrode and the common electrode, forming a pixel defining layer surrounding around an emission area where the pixel electrode, the common electrode, and the light emitting element are to be arranged on the substrate. Edge portions of the pixel electrode and the common electrode may be formed on a side surface of the pixel defining layer.

In an embodiment, the method may further include: before the arranging of the light emitting element after the forming of the pixel electrode and the common electrode, forming a pixel defining layer surrounding around an emission area where the pixel electrode and the common electrode are arranged on the substrate.

According to one or more embodiments of the present disclosure, an electronic device includes: a display module including a display panel; and a processor configured to transmit an image data signal to the display module. The display panel includes: a pixel electrode and a common electrode spaced from each other on a substrate; and a light emitting element on the pixel electrode and the common electrode, and electrically connected between the pixel electrode and the common electrode. The pixel electrode and the common electrode respectively include reflective layers overlapping with different parts of the light emitting element from each other.

In an embodiment, the display panel may further include a pixel defining layer surrounding around the light emitting element and spaced from the light emitting element.

In an embodiment, edge portions of the pixel electrode and the common electrode may be located on a side surface of the pixel defining layer.

In an embodiment, each of the pixel electrode and the common electrode may have a three-layered structure of indium-tin oxide (ITO), silver (Ag), and indium-tin oxide (ITO).

In an embodiment, the display panel may further include: an adhesive layer covering a part of the pixel electrode and a part of the common electrode, and including a portion overlapping with the light emitting element from under the light emitting element; a first connection electrode located on the pixel electrode and the adhesive layer, and connecting a part of the light emitting element to the pixel electrode; and a second connection electrode located on the common electrode and the adhesive layer, and connecting another part of the light emitting element to the common electrode.

According to some embodiments of the present disclosure, a display device and an electronic device may include a light emitting element, and a pixel electrode layer located under the light emitting element. The pixel electrode layer may include a pixel electrode electrically connected to a part of the light emitting element, and may selectively further include a common electrode electrically connected to another part of the light emitting element. In some embodiments, the pixel electrode layer may include a reflective layer. Accordingly, a light efficiency of the display device and the electronic device may be improved, and a manufacturing process of the display device and the electronic device may be simplified.

According to some embodiments of the present disclosure, the display device and the electronic device may further include a pixel defining layer surrounding (e.g., around a periphery of) an emission area where the light emitting element is located. In some embodiments, patterns, for example, such as the common electrode and the pixel electrode, of the pixel electrode layer located in each emission area may be partially located on a side surface of the pixel defining layer. Accordingly, a light output amount and a reflectivity of light emitted from the light emitting element may be further increased, and a light efficiency of the display device and the electronic device may be improved (e.g., may be more effectively improved).

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view illustrating a display device according to an embodiment;

FIG. 2 is a plan view illustrating a display panel according to an embodiment;

FIG. 3 is a block diagram illustrating a display device according to an embodiment;

FIG. 4 is an equivalent circuit diagram illustrating a sub-pixel according to an embodiment;

FIG. 5 is a waveform diagram showing driving signals of a sub-pixel according to an embodiment;

FIG. 6 is a plan view illustrating a display panel according to an embodiment;

FIG. 7 is a plan view illustrating a display panel according to an embodiment;

FIG. 8 is a cross-sectional view illustrating a display panel according to an embodiment;

FIG. 9 is a cross-sectional view showing the area A1 of FIG. 8 in more detail;

FIG. 10 is a cross-sectional view showing the area A2 of FIG. 8 in more detail;

FIG. 11 is a cross-sectional view illustrating a display panel according to an embodiment;

FIG. 12 is a cross-sectional view illustrating a display panel according to an embodiment;

FIG. 13 is a cross-sectional view illustrating a power bus line according to an embodiment;

FIG. 14 is a cross-sectional view illustrating a pad according to an embodiment;

FIG. 15 is a cross-sectional view illustrating a pad according to an embodiment;

FIGS. 16-19 are cross-sectional views showing a method for manufacturing a display device according to an embodiment;

FIGS. 20-22 are cross-sectional views showing a method for manufacturing a display device according to an embodiment;

FIGS. 23-26 are cross-sectional views showing a method for manufacturing a display device according to an embodiment;

FIG. 27 is a block diagram of an electronic device according to an embodiment; and

FIG. 28 is schematic views of some electronic devices according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

The electronic or electric devices and/or any other relevant devices or components according to embodiments of the present disclosure described herein (e.g., the various modules, units, and the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

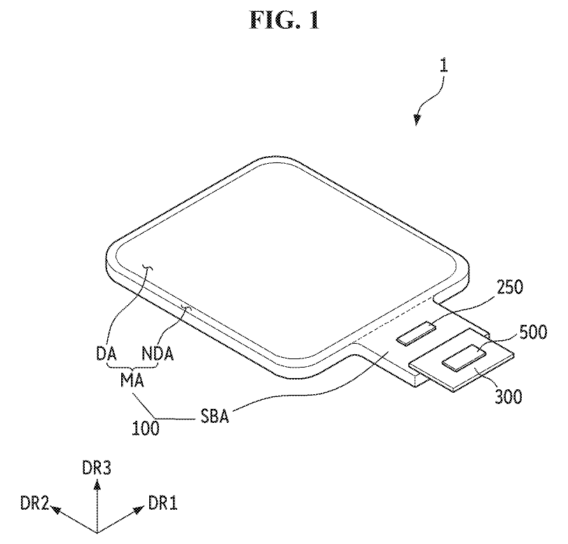

FIG. 1 is a perspective view illustrating a display device according to an embodiment.

Referring to FIG. 1, a display device 1 may be a device capable of providing an image, such as a moving image or a still image. For example, the display device 1 may be a device that includes a display module (e.g., a display or a touch-display) including a display panel 100, and thus, may display an image. As an example, the display device 1 may refer to all suitable electronic devices that provide a display screen on which an image may be displayed, or that include the display module for displaying an image. The display device 1 may be included in an electronic device that provides a display screen, and may form the display screen of the electronic device.

For example, the display device 1 may be included in various suitable electronic devices, such as televisions, laptop computers, monitors, billboards, and the Internet of Things (IOT) devices, as well as portable electronic devices, such as mobile phones, smart phones, tablet personal computers (tablet PCs), smart watches, watch phones, mobile communication terminals, electronic notebooks, electronic books, portable multimedia players (PMPs), navigation systems, and ultra mobile PCs (UMPCs), and used as a display screen. In addition, the display device 1 may be included in other suitable electronic devices, such as a virtual reality (VR) device, an augmented reality (AR) device, or the like, and used to display an image in the electronic device.

In FIG. 1, the display module, which is a main component of the display device 1, is illustrated. In an embodiment, the display device 1 (or an electronic device including the display module) may further include an additional component. For example, the display device 1 may further include a housing or a casing that accommodates the display module of FIG. 1.

In an embodiment, the display device 1 may be a light emitting display device, such as an organic light emitting display using an organic light emitting diode, a quantum dot light emitting display including a quantum dot light emitting layer, an inorganic light emitting display including an inorganic semiconductor, and a micro or nano light emitting display using a micro or nano light emitting diode (LED). Hereinafter, for convenience of illustration, as a representative example of the display device 1, a micro or nano light emitting display including a micro or nano light emitting diode may be described in more detail. However, the present disclosure is not limited thereto. For example, the kind of light emitting element included in the display device 1 is not limited to a micro or nano light emitting diode, and the display device 1 may include a light emitting element of another suitable kind and/or shape. Further, the display device 1 is not limited to a light emitting display device, and the kind and/or shape of the display device 1 may be variously modified as needed or desired.

The display device 1 may include a display panel 100, a display driving circuit 250, a circuit board 300, and a power supply unit (e.g., a power supply) 500. The display panel 100, the display driving circuit 250, the circuit board 300, and the power supply unit 500 may be included in the display module of the display device 1.

In an embodiment, the display panel 100 may have a substantially quadrilateral planar shape. For example, the display panel 100 may have a substantially quadrilateral shape on a plane defined by a first direction DR1 and a second direction DR2 crossing or intersecting each other. The corners of the display panel 100 may be rounded, or may be right-angled. The planar shape of the display panel 100 is not limited to the rectangular shape, and may be formed in another suitable polygonal shape, a circular shape, or an elliptical shape. The display panel 100 may be flat or substantially flat, but is not limited thereto. For example, the display panel 100 may include a curved portion in at least a part (e.g., left and right ends). In an embodiment, the display panel 100 may be formed to be flexible so that it may be curved, bent, folded, or rolled.

The display panel 100 may include a main region MA where an image is displayed. In an embodiment, the display panel 100 may further include a sub-region SBA.

The main region MA may include a display area DA for displaying an image, and a non-display area NDA that is a peripheral area of the display area DA. The display area DA may include pixels to display an image. Each of the pixels may include a plurality of sub-pixels. For example, each of the pixels may include a first sub-pixel that emits light of a first color, a second sub-pixel that emits light of a second color, and a third sub-pixel that emits light of a third color, but the present disclosure is not limited thereto.

The sub-region SBA may protrude from one side of the main region MA in the second direction DR2 (e.g., a longitudinal direction). Although FIG. 1 shows a state in which the sub-region SBA is unfolded, the sub-region SBA may be bent. When the sub-region SBA is bent, the sub-region SBA may overlap with the main region MA in a third direction DR3, which is the thickness direction of the display panel 100, and may be located on a bottom surface of the display panel 100. The display driving circuit 250 may be arranged in the sub-region SBA.

The display driving circuit 250 may generate signals and voltages (e.g., driving signals and driving voltages of the display panel 100) for driving the display panel 100. The display driving circuit 250 may be formed as an integrated circuit (IC), and may be attached onto the display panel 100 by a chip on glass (COG) method, a chip on plastic (COP) method, or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA of the display panel 100, and may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a printed circuit board, or a flexible film, such as a chip on film.

The power supply unit 500 may generate panel driving voltages according to a power voltage supplied from the outside. The power supply unit 500 may be formed as an integrated circuit (IC), and may be attached to the circuit board 300 by a COF method.

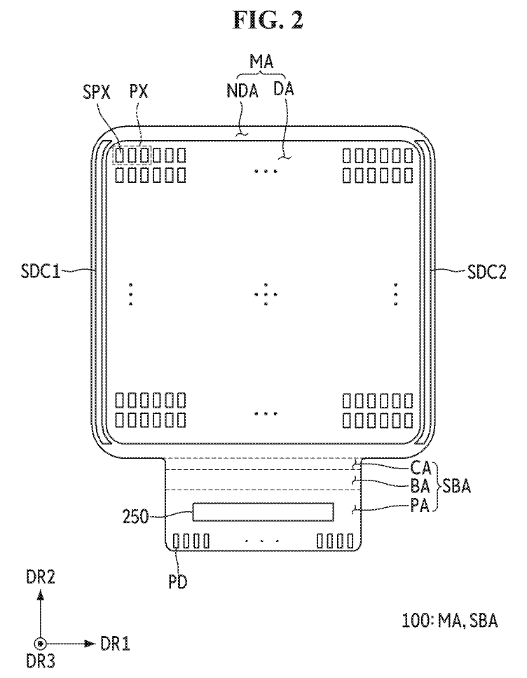

FIG. 2 is a plan view illustrating a display panel according to an embodiment. In FIG. 2, the sub-region SBA is illustrated in an unfolded state.

Referring to FIGS. 1 and 2, the display panel 100 may include the main region MA and the sub-region SBA.

The main region MA may include the display area DA and the non-display area NDA. The display area DA may occupy most of the main region MA.

The display area DA may include pixels PX for displaying an image. Each of the pixels PX may include a plurality of sub-pixels SPX. The pixel PX may be defined as a minimum unit sub-pixel group capable of expressing a white grayscale (e.g., a white grayscale value or level). For example, the pixel PX may include three sub-pixels SPX that emit light of different colors from each other. However, the number, kind, and/or ratio of the sub-pixels SPX included in each pixel PX may be variously modified as needed or desired.

The non-display area NDA may be located adjacent to the display area DA. For example, the non-display area NDA may surround (e.g., around a periphery of) the display area DA. The non-display area NDA may be an edge area of the display panel 100.

In an embodiment, a first scan driver SDC1 and a second scan driver SDC2 may be located in the non-display area NDA. The first scan driver SDC1 and the second scan driver SDC2 may be located on different sides of the display area DA from each other. Each of the first scan driver SDC1 and the second scan driver SDC2 may be electrically connected to the display driving circuit 250 through a plurality of wires. Each of the first scan driver SDC1 and the second scan driver SDC2 may receive scan control signals input from the display driving circuit 250, generate scan signals in response to the scan control signals, and output the generated scan signals to scan lines.

Although FIG. 2 shows an embodiment in which the display device 1 (e.g., the display panel 100) includes the first scan driver SDC1 and the second scan driver SDC2, the present disclosure is not limited thereto. For example, the number or location of the scan driver included in the display device 1 may be variously modified as needed or desired.

The sub-region SBA may protrude from one side of the main region MA in the second direction DR2 (e.g., the longitudinal direction). The length of the sub-region SBA in the second direction DR2 may be less than the length of the main region MA in the second direction DR2. The length of the sub-region SBA in the first direction DR1 may be less than or equal to the length of the main region MA in the first direction DR1. The sub-region SBA may be bent, so that at least a part of the sub-region SBA may overlap with the main region MA in the third direction DR3. For example, a part of the sub-region SBA may be located under the main region MA.

The sub-region SBA may include a connection area CA, a pad area PA, and a bending area BA.

The connection area CA may be an area protruding from one side of the main region MA in the second direction DR2. One side of the connection area CA may be in contact with the non-display area NDA of the main region MA, and another side of the connection area CA may be in contact with the bending area BA.

The pad area PA may be an area on which pads PD and the display driving circuit 250 are arranged. The display driving circuit 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA may be an area that may be bent. When the display panel 100 is bent in the bending area BA, the pad area PA may be located under the connection area CA and the main region MA. The bending area BA may be located between the connection area CA and the pad area PA. One side of the bending area BA may be in contact with the connection area CA, and another side of the bending area BA may be in contact with the pad area PA.

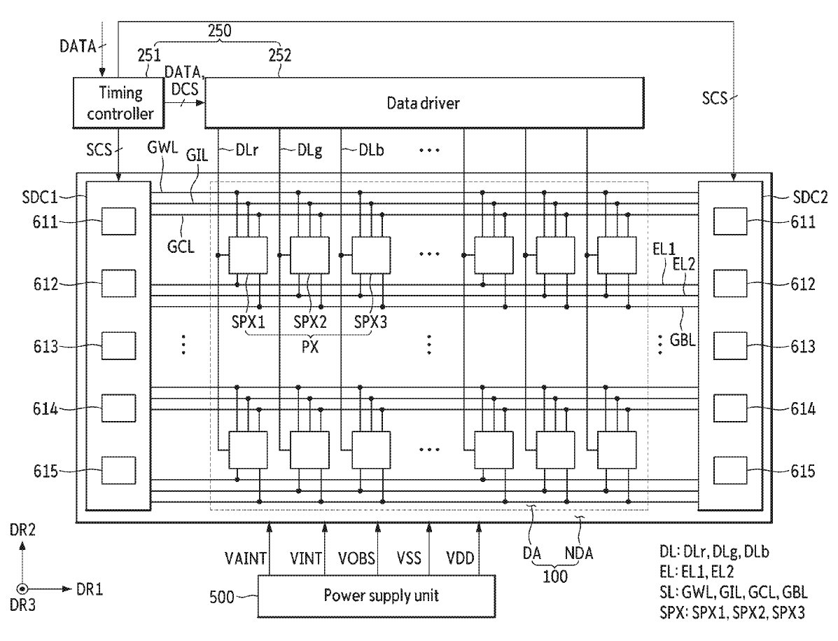

FIG. 3 is a block diagram illustrating a display device according to an embodiment.

Referring to FIG. 3, the display area DA may include pixels PX, scan lines SL, emission control lines EL, and data lines DL.

The pixels PX may be arranged along the first direction DR1 and the second direction DR2. For example, the pixels PX may be arranged in a matrix form along the first direction DR1 and the second direction DR2. The scan lines SL and the emission control lines EL may extend in the first direction DR1, and be arranged along the second direction DR2. The data lines DL may extend in the second direction DR2, and may be arranged along the first direction DR1. The scan lines SL may include write scan lines GWL, initialization scan lines GIL, control scan lines GCL, and bias scan lines GBL. The configuration of the scan lines SL may be variously modified according to the structure or driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, the light of the second color, and the light of the third color may be a red light (e.g., light in a red wavelength band having a main peak wavelength of about 600 nm to 750 nm), a green light (e.g., light in a green wavelength band having a main peak wavelength of about 480 nm to 560 nm), and a blue light (e.g., light in a blue wavelength band having a main peak wavelength of about 370 nm to 460 nm), respectively, but the present disclosure is not limited thereto. In an embodiment, the first sub-pixel SPX1, the second sub-pixel SPX2, and the third sub-pixel SPX3 of each of the pixels PX may be arranged along the first direction DR1. The number, kind, arrangement structure, and/or emission wavelength of the sub-pixels SPX included in each of the pixels PX may be variously modified as needed or desired.

Each of the sub-pixels SPX may be connected to any one of the write scan lines GWL, any one of the initialization scan lines GIL, any one of the control scan lines GCL, any one of the bias scan lines GBL, any one of the emission control lines EL, and any one of the data lines DL. As used herein, a "connection" may include a "physical connection" and/or an "electrical connection."

Each of the plurality of sub-pixels SPX may receive the data voltage of a corresponding data line DL according to the write scan signal of a corresponding write scan line GWL. Each of the plurality of sub-pixels SPX may include a light emitting element that emits light having a luminance corresponding to the data voltage. The plurality of sub-pixels SPX included in each pixel PX may be connected to different data lines DL from each other. For example, the first sub-pixel SPX1, the second sub-pixel SPX2, and the third sub-pixel SPX3 may be connected to a first data line DLr, a second data line DLg, and a third data line DLb, respectively. Accordingly, the luminance of each of the first sub-pixel SPX1, the second sub-pixel SPX2, and the third sub-pixel SPX3 may be controlled individually.

In an embodiment, each of the pixels PX may be connected to two or more emission control lines EL, and an emission period (e.g., on-duty ratio) of at least two of the sub-pixels SPX included in each pixel PX may be controlled independently and/or individually by different emission control signals supplied to the different emission control lines EL. For example, in each horizontal line (e.g., in each pixel row) of the display area DA, a first emission control line EL1 and a second emission control line EL2, which are connected to different sub-pixels SPX among the sub-pixels SPX of the pixels PX arranged on a corresponding horizontal line, may be located. For example, the first emission control line EL1 may be connected to the first sub-pixels SPX1 of the pixels PX arranged on the corresponding horizontal line, and the second emission control line EL2 may be connected to the second sub-pixels SPX2 and the third sub-pixels SPX3 included in the pixels PX of the corresponding horizontal line.

The first sub-pixel SPX1 may emit light during a first emission period in response to a first emission control signal supplied through the first emission control line EL1. The first emission period may be a period during which a driving current may flow through the first sub-pixel SPX1 by the first emission control signal. The second sub-pixel SPX2 and the third sub-pixel SPX3 may emit light during a second emission period in response to a second emission control signal supplied through the second emission control line EL2. The second emission period may be a period during which a driving current may flow through the second sub-pixel SPX2 and the third sub-pixel SPX3 by the second emission control signal. The first emission period and the second emission period may be controlled independently or separately from each other.

In an embodiment, the duration of the first emission period may be different from the duration of the second emission period. For example, the duration of the first emission period may correspond to an on-duty ratio that is adjusted to allow the first sub-pixel SPX1 to emit light with a desired luminance according to a driving current optimized according to a luminous efficiency of the first sub-pixel SPX1 (e.g., a driving current in a range in which the light emitting element of the first sub-pixel SPX1 exhibits an optimal consumption efficiency). The duration of the second emission period may correspond to an on-duty ratio that is adjusted to allow the second sub-pixel SPX2 and the third sub-pixel SPX3 to emit light with a desired luminance according to a driving current optimized according to the luminous efficiency of the second sub-pixel SPX2 and the third sub-pixel SPX3 (e.g., a driving current in a range in which the light emitting elements of the second sub-pixel SPX2 and the third sub-pixel SPX3 exhibit the optimal consumption efficiency). In this case, an emission control signal output unit (e.g., an emission control signal output circuit) 615 included in the first scan driver SDC1 and the second scan driver SDC2 may output emission control signals having different pulse widths from each other to the first emission control line EL1 and the second emission control line EL2.

However, the present disclosure is not limited thereto. For example, in another embodiment, the first sub-pixel SPX1, the second sub-pixel SPX2, and the third sub-pixel SPX3 included in one pixel PX may be commonly connected to one emission control line EL. For example, one emission control line EL may be located in one horizontal line, and the sub-pixels SPX located in the one horizontal line may be commonly connected to the one emission control line EL. In this case, the emission periods of the first sub-pixel SPX1, the second sub-pixel SPX2, and the third sub-pixel SPX3 may be controlled by the emission control signal supplied to the one emission control line EL.

The first scan driver SDC1, the second scan driver SDC2, and the display driving circuit 250 may be located in the non-display area NDA.

Each of the first scan driver SDC1 and the second scan driver SDC2 may be electrically connected to the pixels PX through the scan lines SL and the emission control lines EL. For example, each of the first scan driver SDC1 and the second scan driver SDC2 may be electrically connected to the sub-pixels SPX of each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit or circuit 611, an initialization scan signal output unit or circuit 612, a control scan signal output unit or circuit 613, a bias scan signal output unit or circuit 614, and the emission control signal output unit or circuit 615. Each of the write scan signal output unit 611, the initialization scan signal output unit 612, the control scan signal output unit 613, the bias scan signal output unit 614, and the emission control signal output unit 615 may receive a scan timing control signal SCS from a timing controller 251.

The write scan signal output unit 611 may generate write scan signals in response to the scan timing control signal SCS, and may sequentially output them to the write scan lines GWL.

The initialization scan signal output unit 612 may generate initialization scan signals in response to the scan timing control signal SCS, and may sequentially output them to the initialization scan lines GIL.

The control scan signal output unit 613 may generate control scan signals in response to the scan timing control signal SCS, and may sequentially output them to the control scan lines GCL.

The bias scan signal output unit 614 may generate bias scan signals according to the scan timing control signal SCS, and may output them sequentially to the bias scan lines GBL.

The emission control signal output unit 615 may generate emission control signals according to the scan timing control signal SCS, and may sequentially output them to the emission control lines EL. In an embodiment, when the sub-pixels SPX of each horizontal line are divided and connected to the plurality of emission control lines EL (e.g., the first emission control line EL1 and the second emission control line EL2 of each horizontal line), the emission control signal output unit 615 may output each emission control signal to the plurality of emission control lines EL for each horizontal period.

The display driving circuit 250 may include the timing controller 251 and a data driver 252.

The data driver 252 may be electrically connected to the pixels PX through the data lines DL. For example, the data driver 252 may be electrically connected to the sub-pixels SPX of each pixel PX through the first data line DLr, the second data line DLg, and the third data line DLb.

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. The sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate panel driving voltages according to a power voltage supplied from the outside. For example, the power supply unit 500 may generate and supply a first driving voltage VDD, a second driving voltage VSS, a third driving voltage VINT, a fourth driving voltage VAINT, and a fifth driving voltage VOBS to the display panel 100. The first driving voltage VDD, the second driving voltage VSS, the third driving voltage VINT, the fourth driving voltage VAINT, and the fifth driving voltage VOBS may be supplied to the sub-pixels SPX through respective power lines connected between the power supply unit 500 and the sub-pixels SPX, and may be used to drive the sub-pixels SPX. According to the structure or operation method of the sub-pixels SPX, the number and/or kind of panel driving voltages output from the power supply unit 500 may be variously modified.

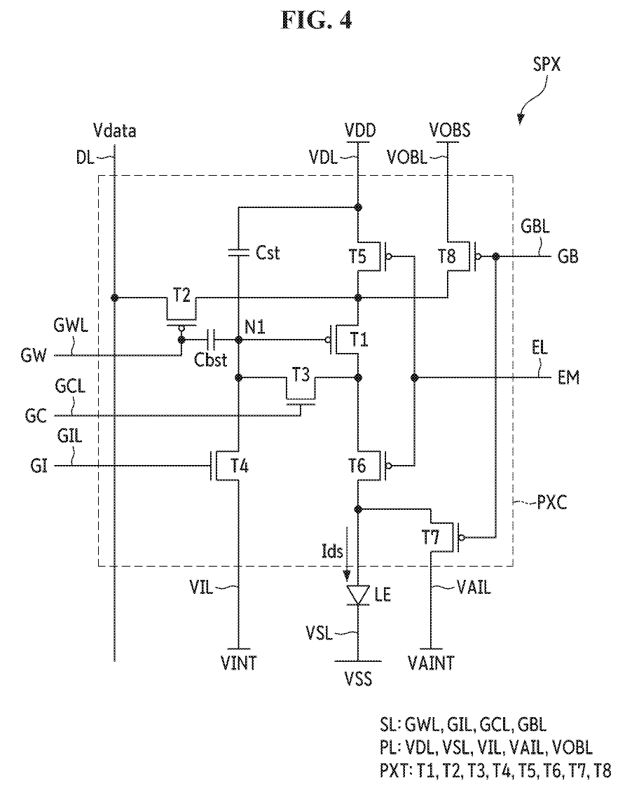

FIG. 4 is an equivalent circuit diagram illustrating a sub-pixel according to an embodiment. For example, FIG. 4 may be an equivalent circuit diagram showing one sub-pixel SPX among the sub-pixels SPX of FIGS. 2 and 3. For example, the sub-pixel SPX of FIG. 4 may be the first sub-pixel SPX1, the second sub-pixel SPX2, or the third sub-pixel SPX3 of FIG. 3. In an embodiment, the circuit configurations of the sub-pixels SPX constituting each pixel PX may be the same or substantially the same as each other.

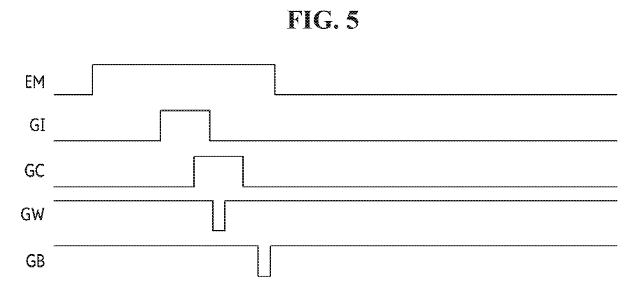

FIG. 5 is a waveform diagram showing driving signals of a sub-pixel according to an embodiment. For example, FIG. 5 shows a write scan signal GW, a control scan signal GC, an initialization scan signal GI, a bias scan signal GB, and an emission control signal EM supplied to the scan lines SL and the emission control line EL of FIG. 4.

Referring to FIGS. 4 and 5 in addition to FIGS. 1 to 3, each of the sub-pixels SPX may include a pixel circuit PXC, and a light emitting element LE electrically connected to the pixel circuit PXC.

The sub-pixel SPX may be connected to at least one scan driver through the scan lines SL and the emission control line EL. For example, the sub-pixel SPX may be connected to the first scan driver SDC1 and/or the second scan driver SDC2 through the write scan line GWL, the initialization scan line GIL, the control scan line GCL, the bias scan line GBL, and the emission control line EL. The first scan driver SDC1 and the second scan driver SDC2 may output the write scan signal GW, the initialization scan signal GI, the control scan signal GC, the bias scan signal GB, and the emission control signal EM to the write scan line GWL, the initialization scan line GIL, the control scan line GCL, the bias scan line GBL, and the emission control line EL, respectively.

When the sub-pixel SPX is the first sub-pixel SPX1, the sub-pixel SPX may be connected to the first emission control line EL1 located on a corresponding horizontal line, and may receive the emission control signal EM (also referred to as a "first emission control signal") from the first emission control line EL1. When the sub-pixel SPX is the second sub-pixel SPX2 or the third sub-pixel SPX3, the sub-pixel SPX may be connected to the second emission control line EL2 located on the corresponding horizontal line, and may receive the emission control signal EM (also referred to as a "second emission control signal") from the second emission control line EL2.

The sub-pixel SPX may be connected to the data driver 252 through the data line DL. The data driver 252 may output a data voltage Vdata corresponding to the image data of each frame to the data line DL.

When the sub-pixel SPX is the first sub-pixel SPX1, the sub-pixel SPX may be connected to the first data line DLr located in a corresponding pixel column. When the sub-pixel SPX is the second sub-pixel SPX2, the sub-pixel SPX may be connected to the second data line DLg located in a corresponding pixel column. When the sub-pixel SPX is the third sub-pixel SPX3, the sub-pixel SPX may be connected to the third data line DLb located in a corresponding pixel column.

The sub-pixel SPX may be connected to the power supply unit 500 through power lines PL. For example, the sub-pixel SPX may be connected to the power supply unit 500 through a first power line VDL, a second power line VSL, a third power line VIL, a fourth power line VAIL, and a fifth power line VOBL. The power supply unit 500 may supply the first driving voltage VDD, the second driving voltage VSS, the third driving voltage VINT, the fourth driving voltage VAINT, and the fifth driving voltage VOBS to the first power line VDL, the second power line VSL, the third power line VIL, the fourth power line VAIL, and the fifth power line VOBL, respectively. In an embodiment, the first driving voltage VDD, the second driving voltage VSS, the third driving voltage VINT, the fourth driving voltage VAINT, and the fifth driving voltage VOBS may be a high potential pixel voltage (e.g., an anode voltage), a low potential pixel voltage (e.g., a cathode voltage or common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals (e.g., the write scan signal GW, the initialization scan signal GI, the control scan signal GC, the bias scan signal GB, the emission control signal EM, and the data voltage Vdata) supplied to the sub-pixel SPX. The emission timing and luminance of the light emitting element LE may be controlled by the pixel circuit PXC.

The pixel circuit PXC may include pixel transistors PXT and a storage capacitor Cst. In an embodiment, the pixel circuit PXC may further include a boosting capacitor Cbst.

In an embodiment, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In an embodiment, the sub-pixel SPX may include different kinds of pixel transistors PXT. For example, the first, second, fifth, sixth, seventh, and eighth transistors T1, T2, T5, T6, T7, and T8 may be P-type transistors (e.g., P-type polycrystalline silicon transistors including active layers containing polycrystalline silicon), and the third and fourth transistors T3 and T4 may be N-type transistors (e.g., N-type oxide transistors including active layers containing an oxide semiconductor). In an embodiment, the active layers of the P-type transistors (e.g., the active layers containing polycrystalline silicon) and the active layers of the N-type transistors (e.g., the active layers containing an oxide semiconductor) may be located in different layers from each other within the display panel 100 (e.g., a backplane layer of the display panel 100). However, the present disclosure is not limited thereto. For example, the pixel transistors PXT according to another embodiment may include active layers including the same semiconductor material as each other, and may be formed as transistors of the same type as each other.

The first transistor T1 may be connected between the fifth transistor T5 and the sixth transistor T6. The first transistor T1 may be connected to the first power line VDL via the fifth transistor T5, and may be connected to the light emitting element LE via the sixth transistor T6. The gate electrode of the first transistor T1 may be connected to a first node N1. The first transistor T1 may control the driving current Ids flowing through the sub-pixel SPX according to the voltage of the first node N1 applied to the gate electrode (e.g., a voltage corresponding to the data voltage Vdata).

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of a gate-on voltage (e.g., a low level voltage at which the second transistor T2 can be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and the first node N1. The gate electrode of the third transistor T3 may be connected to the control scan line GCL. The third transistor T3 may be turned on by the control scan signal GC of a gate-on voltage (e.g., a high level voltage at which the third transistor T3 can be turned on) supplied from the control scan line GCL, to connect the gate electrode of the first transistor T1 to the second electrode of the first transistor T1. When the third transistor T3 is turned on, the first transistor T1 may be driven as a diode (e.g., may be diode-connected), and a voltage corresponding to the data voltage Vdata may be applied to the first node N1.

The fourth transistor T4 may be connected between the first node N1 and the third power line VIL. The gate electrode of the fourth transistor T4 may be connected to the initialization scan line GIL. The fourth transistor T4 may be turned on by the initialization scan signal GI of a gate-on voltage (e.g., a high level voltage at which the fourth transistor T4 can be turned on) supplied from the initialization scan line GIL, to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. The gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage (e.g., a low level voltage at which the fifth transistor T5 can be turned on) supplied from the emission control line EL, to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light emitting element LE. The gate electrode of the sixth transistor T6 may be connected to the emission control line EL. The sixth transistor T6 may be turned on by the emission control signal EM of a gate-on voltage (e.g., a low level voltage at which the sixth transistor T6 can be turned on) supplied from the emission control line EL, to connect the second electrode of the first transistor T1 to the light emitting element LE.

The seventh transistor T7 may be connected between the first electrode of the light emitting element LE (e.g., the anode electrode connected to the sixth transistor T6) and the fourth power line VAIL. The gate electrode of the seventh transistor T7 may be connected to the bias scan line GBL. The seventh transistor T7 may be turned on by the bias scan signal GB of a gate-on voltage (e.g., a low level voltage at which the seventh transistor T7 can be turned on) supplied from the bias scan line GBL, to connect the first electrode of the light emitting element LE to the fourth power line VAIL. When the seventh transistor T7 is turned on, the voltage of the first electrode of the light emitting element LE may be initialized to the fourth driving voltage VAINT of the fourth power line VAIL.

The eighth transistor T8 may be connected between the fifth power line VOBL and the first electrode of the first transistor T1. The gate electrode of the eighth transistor T8 may be connected to the bias scan line GBL. The eighth transistor T8 may be turned on by the bias scan signal GB of a gate-on voltage supplied from the bias scan line GBL, to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In an embodiment, the fifth driving voltage VOBS may be a bias voltage having a voltage level suitable for compensating for hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by a coupling of the boosting capacitor Cbst, thereby stabilizing the operation of the first transistor T1. The boosting capacitor Cbst may be formed by a parasitic capacitance formed between the first node N1 and the write scan line GWL, or may be designed separately.

The sub-pixel SPX may emit light during a partial period of each frame period, which corresponds to the on-duty ratio, and may not emit light during a remaining period. The emission period and the non-emission period of the sub-pixel SPX may be controlled by the emission control signal EM.

A period during which the fifth transistor T5 and the sixth transistor T6 are turned off (e.g., a period during which the emission control signal EM of a high level is supplied to the sub-pixel SPX) may be the non-emission period of the sub-pixel SPX. The non-emission period of the sub-pixel SPX may include an initialization period for initializing a voltage of a specific node (e.g., the first node N1 or the like) of the sub- pixel SPX, and a data write and storage period for charging the storage capacitor Cst with a voltage corresponding to the data voltage Vdata. In an embodiment, the initialization scan signal GI, the control scan signal GC, the write scan signal GW, and the bias scan signal GB of a gate-on voltage may be supplied during the non-emission period of the sub-pixel SPX. In an embodiment, the initialization scan signal GI, the control scan signal GC, and the bias scan signal GB of the gate-on voltage may be sequentially supplied during the non-emission period of the sub-pixel SPX. The periods in which the initialization scan signal GI and the control scan signal GC of the gate-on voltage are supplied may overlap with each other, but the present disclosure is not limited thereto. The write scan signal GW of the gate-on voltage may be supplied during the period in which the control scan signal GC of the gate-on voltage is supplied.

The period during which the fifth transistor T5 and the sixth transistor T6 are turned on (e.g., the period during which the emission control signal EM of a low level is supplied to the sub-pixel SPX) may be the emission period of the sub-pixel SPX. During the emission period of the sub-pixel SPX, the first transistor T1 may supply the driving current Ids corresponding to the voltage of the first node N1 to the light emitting element LE.

The light emitting element LE may be connected between the pixel circuit PXC and the second power line VSL. For example, the first electrode (e.g., the anode electrode or pixel electrode) of the light emitting element LE may be connected to a node between the sixth transistor T6 and the seventh transistor T7, and the second electrode (e.g., the cathode electrode or common electrode) of the light emitting element LE may be connected to the second power line VSL. The light emitting element LE may emit light corresponding to the driving current Ids supplied from the pixel circuit PXC.

In an embodiment, the sub-pixel SPX may include a single light emitting element LE, but the present disclosure is not limited thereto. For example, the sub-pixel PX may include a plurality of light emitting elements LE.

In an embodiment, the light emitting element LE may be a micro light emitting diode containing an inorganic compound, such as a nitride-based or phosphide-based semiconductor material, but the present disclosure is not limited thereto. For example, the light emitting element LE may be an organic light emitting element, a quantum dot light emitting element, or another kind of light emitting element. In addition, the size or shape of the light emitting element LE may be variously modified as needed or desired.

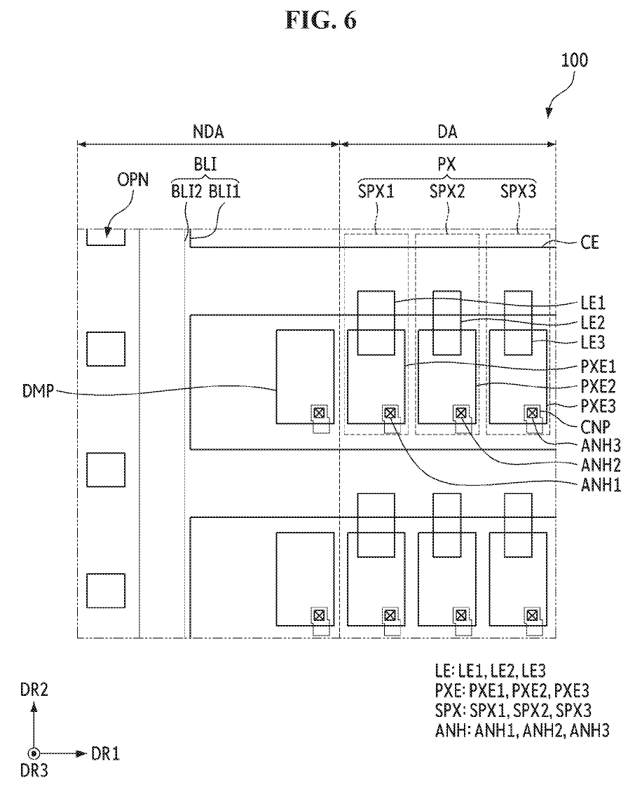

FIG. 6 is a plan view illustrating a display panel according to an embodiment. For example, FIG. 6 shows a part of the display area DA where two pixels PX are sequentially located along the second direction DR2, and a part of the non-display area NDA adjacent to the part of the display area DA and where a power bus line BLI is located.

FIG. 6 shows pixel electrodes PXE, a common electrode CE, the light emitting elements LE, and a first wiring layer BLI1 of the power bus line BLI, as an example of some of the elements included in the light emitting element layer of the display panel 100 according to an embodiment. Further, FIG. 6 shows connection patterns CNP connected to the pixel electrodes PXE, and a second wiring layer BLI2 of the power bus line BLI, as an example of some of the elements included in the backplane layer of the display panel 100 according to an embodiment.

Referring to FIG. 6, each of the sub-pixels SPX may include the pixel electrode PXE, and the light emitting element LE located on the pixel electrode PXE. In an embodiment, when the light emitting element LE is a micro LED of a flip-chip kind or a lateral kind, each of the sub-pixels SPX may further include the common electrode CE located on one surface (e.g., a bottom surface) of the light emitting element LE together with the pixel electrode PXE. In another embodiment, when the light emitting element LE is a micro LED of a vertical kind, the light emitting element LE of each of the sub-pixels SPX may be located on the pixel electrode PXE, and the common electrode CE (e.g., the common electrode CE located as a common layer in the entire display area DA) may be located on the light emitting elements LE of the sub-pixels SPX. FIG. 6 shows the display panel 100 including the light emitting elements LE of a flip-chip kind. The pixel electrode PXE may also be referred to as the anode electrode or the first electrode, and the common electrode CE may also be referred to as the cathode electrode or the second electrode.

In an embodiment, the sub-pixels SPX of each pixel PX may be arranged along the first direction DR1, and may share one common electrode CE. For example, the common electrode CE may extend in the first direction DR1 in each pixel row (e.g., in each horizontal line) of the display area DA, and the sub-pixels SPX of the pixels PX located on a corresponding pixel row may share one common electrode CE.

The first sub-pixel SPX1 may include a first pixel electrode PXE1 and the common electrode CE (or a part of the common electrode CE) spaced apart from each other, and a first light emitting element LE1 located on the first pixel electrode PXE1 and the common electrode CE. The first pixel electrode PXE1 may refer to the pixel electrode PXE of the first sub-pixel SPX1. The first light emitting element LE1 may refer to the light emitting element LE of the first sub-pixel SPX1. The first light emitting element LE1 may be electrically connected between the first pixel electrode PXE1 and the common electrode CE.

The second sub-pixel SPX2 may include a second pixel electrode PXE2 and the common electrode CE spaced apart from each other, and a second light emitting element LE2 located on the second pixel electrode PXE2 and the common electrode CE. The second pixel electrode PXE2 may refer to the pixel electrode PXE of the second sub-pixel SPX2. The second light emitting element LE2 may refer to the light emitting element LE of the second sub-pixel SPX2. The second light emitting element LE2 may be electrically connected between the second pixel electrode PXE2 and the common electrode CE.

The third sub-pixel SPX3 may include a third pixel electrode PXE3 and the common electrode CE spaced apart from each other, and a third light emitting element LE3 located on the third pixel electrode PXE3 and the common electrode CE. The third pixel electrode PXE3 may refer to the pixel electrode PXE of the third sub-pixel SPX3. The third light emitting element LE3 may refer to the light emitting element LE of the third sub-pixel SPX3. The third light emitting element LE3 may be electrically connected between the third pixel electrode PXE3 and the common electrode CE.

In an embodiment, the first pixel electrode PXE1, the second pixel electrode PXE2, and the third pixel electrode PXE3 of each pixel PX may be arranged along the first direction DR1, and may be spaced apart from the common electrode CE in the second direction DR2. For example, in each pixel PX, the first pixel electrode PXE1, the second pixel electrode PXE2, and the third pixel electrode PXE3 may be arranged sequentially along the first direction DR1. Further, the first pixel electrode PXE1, the second pixel electrode PXE2, and the third pixel electrode PXE3 may face different parts of the common electrode CE in the second direction DR2. In another embodiment, when the sub-pixels SPX include a micro LED of a vertical kind, the first pixel electrode PXE1, the second pixel electrode PXE2, and the third pixel electrode PXE3 may face the common electrode CE in the third direction DR3.

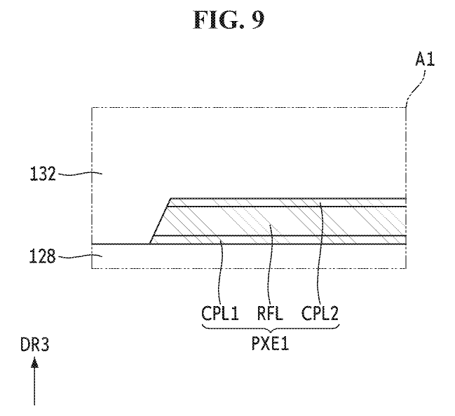

The pixel electrodes PXE and the common electrode CE may be formed as a conductive pattern including a conductive material. In an embodiment, the pixel electrodes PXE and the common electrode CE may include a reflective layer (e.g., a reflective layer RFL of FIG. 9) including a suitable material having a high reflectivity for light emitted from the light emitting element LE. For example, the pixel electrodes PXE and the common electrode CE may include a reflective layer including silver (Ag) or aluminum (Al), or another suitable metal having a high light reflectivity.

The pixel electrodes PXE and the common electrode CE may each be formed as a single layer including a reflective layer, or may be formed as multiple layers including an additional conductive layer or capping layer located on at least one surface (e.g., at least one of the top surface or the bottom surface) of the reflective layer. For example, the pixel electrodes PXE and the common electrode CE may be formed in a three-layered structure (ITO/Ag/ITO) of indium tin oxide (ITO), silver (Ag), and indium tin oxide (ITO), but the present disclosure is not limited thereto. For example, any suitable material for satisfying a required or desired level of conductivity, reliability, and light reflectivity of the pixel electrodes PXE and the common electrode CE may be used to form the pixel electrodes PXE and the common electrode CE.

The common electrode CE and the pixel electrode PXE of each of the sub-pixels SPX may overlap with different parts of the light emitting element LE. Accordingly, the respective reflective layers included in the common electrode CE and the pixel electrode PXE of each of the sub-pixels SPX may overlap with different parts of the light emitting element LE. For example, the pixel electrode PXE may be located under a part of the bottom surface of the light emitting element LE, and the common electrode CE may be located under another part of the bottom surface of the light emitting element LE.

Because the pixel electrodes PXE and the common electrode CE include the reflective layer, the pixel electrodes PXE and the common electrode CE may also function as a reflective plate. For example, the pixel electrodes PXE and the common electrode CE may each be integrally formed with a reflective plate that is located under the light emitting element LE and reflects light propagating toward the bottom of the light emitting element LE. The pixel electrode PXE of each of the sub-pixels SPX may also be referred to as a first reflective electrode, and the common electrode CE may also be referred to as a second reflective electrode.

The pixel circuit PXC (e.g., see FIG. 4) and the pixel electrode PXE of each of the sub-pixels SPX may be electrically connected to each other through an anode contact hole ANH. For example, the first pixel electrode PXE1 of the first sub-pixel SPX1 may be electrically connected to at least one circuit element (e.g., the sixth and seventh transistors T6 and T7 of FIG. 4) included in the pixel circuit PXC of the first sub-pixel SPX1 through a first anode contact hole ANH1 and/or at least one connection pattern CNP (e.g., the anode connection pattern that connects the first pixel circuit PXC1 to the first light emitting element LE1). The second pixel electrode PXE2 of the second sub-pixel SPX2 may be electrically connected to at least one circuit element included in the pixel circuit PXC of the second sub-pixel SPX2 through a second anode contact hole ANH2 and/or at least one connection pattern CNP, and the third pixel electrode PXE3 of the third sub-pixel SPX3 may be electrically connected to at least one circuit element included in the pixel circuit PXC of the third sub-pixel SPX3 through a third anode contact hole ANH3 and/or at least one connection pattern CNP.

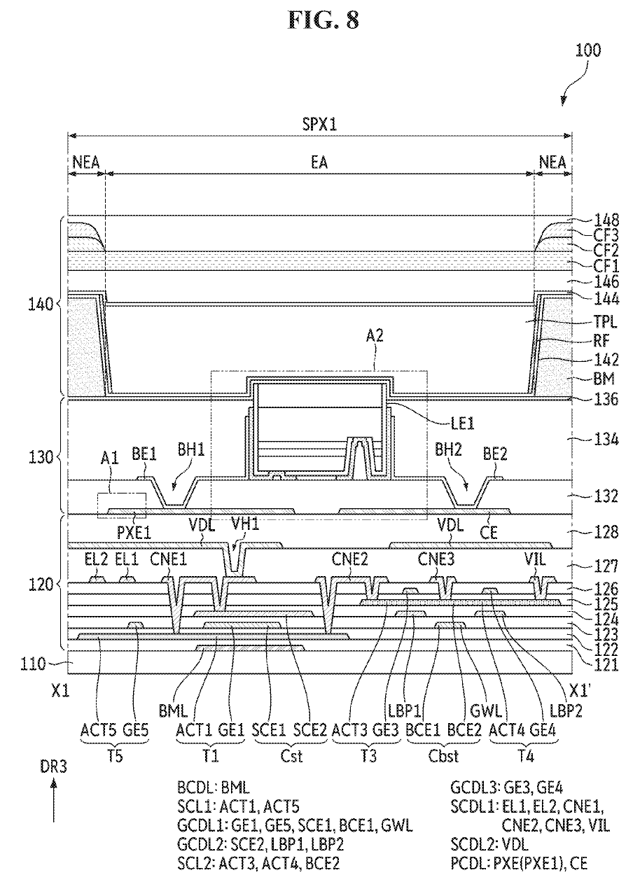

In an embodiment, the connection patterns CNP may be formed as single-layer or multi-layered patterns included in at least one conductive layer among the conductive layers included in the backplane layer of the display panel 100. For example, the connection patterns CNP may be formed as patterns included in the conductive layer (e.g., a second source-drain conductive layer SCDL2 of FIG. 8) that is closest to the light emitting element layer among the conductive layers of the backplane layer, but the present disclosure is not limited thereto. For example, the connection patterns CNP may be formed as patterns included in another conductive layer (e.g., a first source-drain conductive layer SCDL1 of FIG. 8) of the backplane layer. As another example, the display panel 100 may not include the connection patterns CNP of FIG. 6, and each pixel electrode PXE may be directly connected to at least one circuit element included in each pixel circuit PXC through at least one contact hole. The shape or size of the connection pattern CNP included in each sub-pixel SPX may be variously modified as needed or desired.

The light emitting elements LE may be located between the respective pixel electrodes PXE and the common electrode CE. For example, the first light emitting element LE1 may be located on the first pixel electrode PXE1 and the common electrode CE, and a part of the first light emitting element LE1 may overlap with the first pixel electrode PXE1 and another part of the first light emitting element LE1 may overlap with the common electrode CE. The second light emitting element LE2 may be located on the second pixel electrode PXE2 and the common electrode CE, and a part of the second light emitting element LE2 may overlap with the second pixel electrode PXE2 and another part of the second light emitting element LE2 may overlap with the common electrode CE. The third light emitting element LE3 may be located on the third pixel electrode PXE3 and the common electrode CE, and a part of the third light emitting element LE3 may overlap with the third pixel electrode PXE3 and another part of the third light emitting element LE3 may overlap with the common electrode CE.

Each of the light emitting elements LE may emit light of a desired color (e.g., a red light, a green light, a blue light, or a white light). In an embodiment, the first light emitting element LE1, the second light emitting element LE2, and the third light emitting element LE3 may emit light of different colors from each other. For example, the first light emitting element LE1, the second light emitting element LE2, and the third light emitting element LE3 may emit light of a first color (e.g., a red light), light of a second color (e.g., a green light), and light of a third color (e.g., a blue light), respectively.

In an embodiment, the light emitting elements LE of at least two sub-pixels SPX may have different sizes from each other. For example, the size of the first light emitting element LE1 may be larger than the size of each of the second light emitting element LE2 and the third light emitting element LE3. The sizes of the second light emitting element LE2 and the third light emitting element LE3 may be the same or substantially the same as each other, or may be different from each other.

In an embodiment, the light emitting elements LE may have a differentiated or optimized sizes depending on the luminous efficiency of the light emitting elements LE or the like. For example, depending on the luminous efficiency of each of the first light emitting element LE1, the second light emitting element LE2, and the third light emitting element LE3, at least two light emitting elements LE among the first light emitting element LE1, the second light emitting element LE2, and the third light emitting element LE3 may have different sizes from each other. For example, when the luminous efficiency of the first light emitting element LE1 is less than the luminous efficiency of each of the second light emitting element LE2 and the third light emitting element LE3 based on the same size and shape, the size of the first light emitting element LE1 may be larger than the size of each of the second light emitting element LE2 and the third light emitting element LE3. Accordingly, the luminous efficiency of the first light emitting element LE1 may be improved, and a luminous efficiency deviation or variation of the first light emitting element LE1, the second light emitting element LE2, and the third light emitting element LE3 may be reduced or prevented.

In another embodiment, the first light emitting element LE1, the second light emitting element LE2, and the third light emitting element LE3 may emit light of the same color as each other. In this case, at least one of a color filter or a light conversion layer (e.g., a light conversion layer including wavelength conversion particles, such as quantum dots or the like) for converting light emitted from the light emitting element LE of the corresponding sub-pixel SPX to light corresponding to the emission color of the corresponding sub-pixel SPX may be located on at least one light emitting element LE of the first sub-pixel SPX1, the second sub-pixel SPX2, and the third sub-pixel SPX3. When the first light emitting element LE1, the second light emitting element LE2, and the third light emitting element LE3 emit light of the same color as each other, the first light emitting element LE1, the second light emitting element LE2, and the third light emitting element LE3 may have the same or substantially the same size as each other, or may have different sizes from each other. For example, depending on the light conversion efficiency by the light conversion layer, at least one of the size of the light emitting elements LE of the sub-pixels SPX or the area of the emission areas of the sub-pixels SPX may be differentiated from each other.

The common electrode CE may be electrically connected to the power bus line BLI to which the second driving voltage VSS is applied. In an embodiment, the common electrode CE may extend to the non-display area NDA around the display area DA, and may be electrically connected to the power bus line BLI in the non-display area NDA. The common electrode CE may be electrically connected to the power bus line BLI through at least one contact hole and/or connection line, or may be integrally formed with at least a part of the power bus line BLI. For example, the power bus line BLI may include a plurality of wiring layers, and one of the plurality of wiring layers and the common electrode CE may be formed as one or substantially one pattern.

In an embodiment, the second power line VSL (e.g., see FIG. 4) to which the second driving voltage VSS is applied may also be located in the display area DA. For example, the second power line VSL crossing, intersecting, or overlapping with the common electrode CE may be located in the backplane layer located under the common electrode CE. In this case, the common electrode CE may be electrically connected to the second power line VSL through at least one contact hole and/or connection line in the display area DA.

The power bus line BLI may be located in the non-display area NDA, and may be located on at least one side of the display area DA. For example, the power bus line BLI may be located on the left side and the right side of the display area DA, and may be further selectively located on at least one of the upper side or the lower side of the display area DA. In FIG. 6, a part of the power bus line BLI located on the left side of the display area DA is illustrated.

The power bus line BLI may be electrically connected to the power supply unit 500 (e.g., see FIG. 3). For example, the power bus line BLI may be electrically connected to the power supply unit 500 through at least one pad PD and/or at least one connection line located in the sub-region SBA and/or the non-display area NDA of the main region MA. Accordingly, the second driving voltage VSS output from the power supply unit 500 may be applied to the power bus line BLI. The power bus line BLI may form a part of the second power line VSL electrically connected between the power supply unit 500 and the sub-pixels SPX. In addition to the above, a connection structure between the common electrode CE and the second power line VSL may be variously modified as needed or desired.

In an embodiment, the power bus line BLI may be formed as multiple layers including the first wiring layer BLI1 and the second wiring layer BLI2. The first wiring layer BLI1 and the second wiring layer BLI2 may be electrically connected to each other. The first wiring layer BLI1 and the second wiring layer BLI2 may also be referred to as a first sub-bus line and a second sub-bus line, respectively.

The first wiring layer BLI1 may be located in the same layer as that of the pixel electrodes PXE and the common electrode CE, and may include a conductive material included in the pixel electrodes PXE and the common electrode CE. In an embodiment, the first wiring layer BLI1 may be integrally formed with the common electrode CE. For example, at least one end of the common electrode CE may extend to the non-display area NDA, and may be connected to the first wiring layer BLI1 of the power bus line BLI.

In an embodiment, the first wiring layer BLI1 may have a width greater than that of the second wiring layer BLI2 in the first direction DR1. For example, the first wiring layer BLI1 may extend further toward an outer edge of the display panel 100 from a portion overlapping with the second wiring layer BLI2, and may cover the scan driver (e.g., the first scan driver SDC1 and the second scan driver SDC2 of FIGS. 2 and 3). The first wiring layer BLI1 may further cover additional wires located between the power bus line BLI and the scan driver, for example, such as wires located in the non-display area NDA and respectively connected to the pixels PX or the scan driver. In an embodiment, the first wiring layer BLI1 may include a plurality of openings OPN. Accordingly, gas generated by outgassing in the display panel 100 may be appropriately discharged.

The second wiring layer BLI2 may overlap with at least a part of the first wiring layer BLI1. In an embodiment, the second wiring layer BLI2 may be located under the first wiring layer BLI1, and may be in contact with the first wiring layer BLI1. For example, an insulating layer that covers an end of the second wiring layer BLI2 may be located between the first wiring layer BLI1 and the second wiring layer BLI2, and the insulating layer may be opened in a region where the first wiring layer BLI1 and the second wiring layer BLI2 overlap with each other. In a portion where the insulating layer is opened, the first wiring layer BLI1 and the second wiring layer BLI2 may be in contact with each other, and may be electrically connected to each other.

In an embodiment, the second wiring layer BLI2 may be formed as a single-layer or multi-layered pattern included in at least one conductive layer among the conductive layers included in the backplane layer of the display panel 100. For example, the second wiring layer BLI2 may be formed as a conductive pattern included in the conductive layer (e.g., the second source-drain conductive layer SCDL2 of FIG. 8) that is closest to the light emitting element layer among the conductive layers of the backplane layer, but the present disclosure is not limited thereto.

In an embodiment, dummy patterns DMP may be further located in the non-display area NDA. For example, the dummy patterns DMP may have a shape and/or size corresponding to those of the pixel electrodes PXE, and may be located around the pixel electrodes PXE located at the outermost edge of the display area DA. In an embodiment, dummy connection patterns and/or dummy pixel circuits connected to the respective dummy patterns DMP through respective dummy holes may be located under the dummy patterns DMP. The dummy patterns DMP, the dummy connection patterns, and/or the dummy pixel circuits may be omitted as needed or desired.

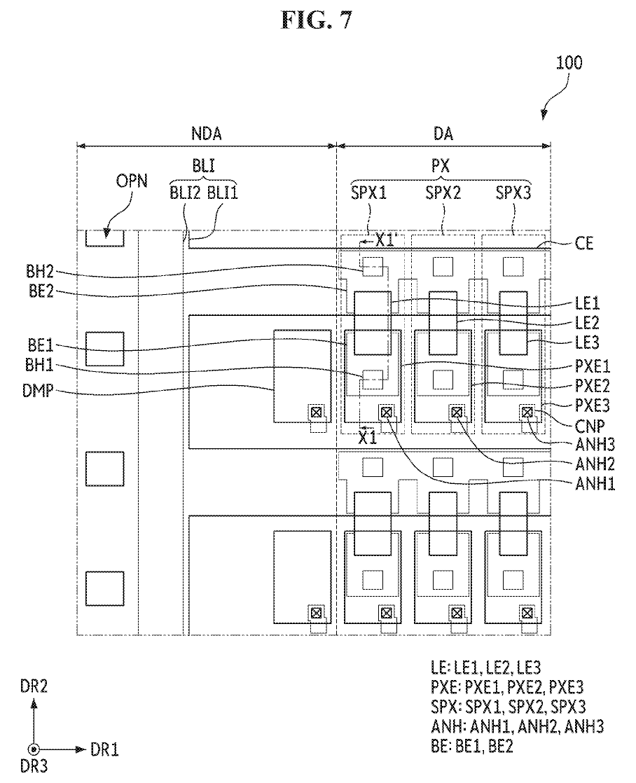

FIG. 7 is a plan view illustrating a display panel according to an embodiment. In comparison with the embodiment illustrated in FIG. 6, FIG. 7 shows a display panel 100 further including connection electrodes BE. In FIG. 7, the components that are the same or substantially the same as (or similar to) those described above are designated with the same reference numerals, and thus, redundant description thereof may not be repeated hereinafter.

Referring to FIGS. 6 and 7, the display panel 100 may further include the connection electrodes BE located in the sub-pixels SPX. For example, each sub-pixel SPX may include a first connection electrode BE1 located on the pixel electrode PXE, and a second connection electrode BE2 located on the common electrode CE.

The first connection electrode BE1 may connect the pixel electrode PXE to the light emitting element LE. For example, in each sub-pixel SPX, the first connection electrode BE1 may be electrically connected to the pixel electrode PXE through a first connection hole BH1. The first connection hole BH1 may be an opening formed in (e.g., penetrating) an insulating layer or an adhesive layer located between the pixel electrode PXE and the light emitting element LE. Further, the first connection electrode BE1 may be in contact with a part (e.g., a side surface on which the first contact electrode of the light emitting element LE is located) of the light emitting element LE located on the pixel electrode PXE, and may be electrically connected to the light emitting element LE.

The second connection electrode BE2 may connect the common electrode CE to the light emitting element LE. For example, in each sub-pixel SPX, the second connection electrode BE2 may be electrically connected to the common electrode CE through a second connection hole BH2. The second connection hole BH2 may be an opening formed in (e.g., penetrating) an insulating layer or an adhesive layer located between the common electrode CE and the light emitting element LE. Further, the second connection electrode BE2 may be in contact with another part (e.g., a side surface on which the second contact electrode of the light emitting element LE is located) of the light emitting element LE located on the common electrode CE, and may be electrically connected to the light emitting element LE. In an embodiment, the second connection electrodes BE2 of the sub-pixels SPX located in one horizontal line or one pixel PX may be integrally formed with each other to form or substantially form one pattern, but the present disclosure is not limited thereto.

Although an embodiment in which the first connection electrode BE1 and the pixel electrode PXE are electrically connected to each other through the first connection hole BH1, and the second connection electrode BE2 and the common electrode CE are electrically connected to each other through the second connection hole BH2 is illustrated in FIG. 7, the present disclosure is not limited thereto. For example, in another embodiment, the insulating layer or the adhesive layer on the pixel electrode PXE and the common electrode CE may partially cover the pixel electrode PXE and the common electrode CE only under the light emitting element LE and/or directly around the light emitting element LE, and may not be located on other parts of the pixel electrode PXE and the common electrode CE. In this case, the first connection hole BH1 and the second connection hole BH2 may be omitted, and the first connection electrode BE1 and the second connection electrode BE2 may be directly located on other parts of the pixel electrode PXE and the common electrode CE, respectively. Further, in another embodiment, each light emitting element LE may be directly located or bonded on each of the pixel electrode PXE and the common electrode CE, and the display panel 100 may not include the connection electrodes BE.

FIG. 8 is a cross-sectional view illustrating a display panel according to an embodiment. For example, FIG. 8 illustrates an example of a cross-section of a portion of the display panel 100 corresponding to the line X1-X1' of FIG. 7.

FIG. 9 is a cross-sectional view showing the area A1 of FIG. 8 in more detail. For example, FIG. 9 shows an example of the cross-section of the first pixel electrode PXE1 included in the first sub-pixel SPX1 in more detail. In an embodiment, the first pixel electrode PXE1, the second pixel electrode PXE2, and the third pixel electrode PXE3 of the first sub-pixel SPX1, the second sub-pixel SPX2, and the third sub-pixel SPX3, and the common electrode CE may have the same or substantially the same (or similar) cross-sectional structures as each other.

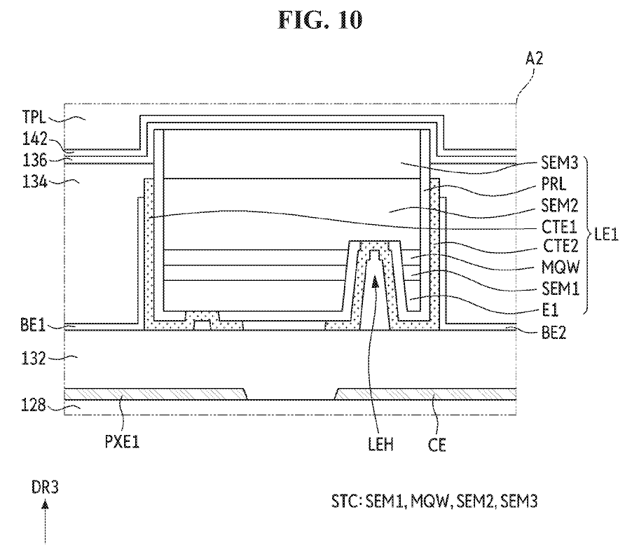

FIG. 10 is a cross-sectional view showing the area A2 of FIG. 8 in more detail. For example, FIG. 10 shows an example of the first light emitting element LE1 included in the first sub-pixel SPX1 in more detail. In an embodiment, the first light emitting element LE1, the second light emitting element LE2, and the third light emitting element LE3 of the first sub-pixel SPX1, the second sub-pixel SPX2, and the third sub- pixel SPX3 may have the same or substantially the same (or similar) cross-sectional structures as each other.

Referring to FIGS. 8 to 10 in addition to FIGS. 1 to 7, the display panel 100 may include a substrate 110, and a backplane layer 120 and a light emitting element layer 130 located on the substrate 110. In an embodiment, the display panel 100 may further include an optical layer 140 located on the light emitting element layer 130. The backplane layer 120, the light emitting element layer 130, and the optical layer 140 may be sequentially located on the substrate 110 along the third direction DR3.

The substrate 110 may include an insulating material, such as glass or a polymer resin. When the substrate 110 includes the polymer resin, it may be a flexible substrate that may be stretched.

The substrate 110 may include the display area DA and the non-display area NDA. The display area DA may include the emission areas EA of the sub-pixels SPX. Each emission area EA may include a light emitting element area where a corresponding light emitting element LE of each sub-pixel SPX is located.

The backplane layer 120 may include circuit elements included in the pixel circuits PXC of the sub-pixels SPX, and wires connected to the sub-pixels SPX. In an embodiment, the backplane layer 120 may be formed entirely on one surface of the substrate 110.

The backplane layer 120 may include at least one semiconductor layer, conductive layers, or insulating layers. In an embodiment, when the pixel circuits PXC include at least two types of pixel transistors PXT containing different materials from each other, the backplane layer 120 may include a plurality of semiconductor layers.

For example, the backplane layer 120 may include a lower conductive layer BCDL, a barrier layer 121 (or a buffer layer), the first semiconductor layer SCL1 (e.g., a polycrystalline silicon semiconductor layer), a first insulating layer 122 (e.g., a first inorganic insulating layer), the first gate conductive layer GCDL1 (e.g., a first conductive layer), a second insulating layer 123 (e.g., a second inorganic insulating layer), the second gate conductive layer GCDL2 (e.g., a second conductive layer), a third insulating layer 124 (e.g., a third inorganic insulating layer), the second semiconductor layer SCL2 (e.g., an oxide semiconductor layer), a fourth insulating layer 125 (e.g., a fourth inorganic insulating layer), the third gate conductive layer GCDL3 (e.g., a third conductive layer), a fifth insulating layer 126 (e.g., a fifth inorganic insulating layer), the first source-drain conductive layer SCDL1 (e.g., a fourth conductive layer), a sixth insulating layer 127 (e.g., a first organic insulating layer), the second source-drain conductive layer SCDL2 (e.g., a fifth conductive layer), and a seventh insulating layer 128 (e.g., a second organic insulating layer) that are sequentially located on the substrate 110 along the third direction DR3.

The lower conductive layer BCDL may include a lower conductive pattern BML located below the first transistor T1. The lower conductive pattern BML may entirely or partially cover the bottom surface of the first active layer ACT1 included in the first transistor T1. For example, the lower conductive pattern BML may be located below the first active layer ACT1 to overlap with a channel region (e.g., a portion of the first active layer ACT1 overlapping with the first gate electrode GE1) of the first active layer ACT1. In an embodiment, the lower conductive layer BCDL may include a light blocking material. For example, the lower conductive layer BCDL may include a metal, and the lower conductive pattern BML may be formed as a lower metal pattern. Accordingly, light may be prevented or substantially prevented from being incident on the channel region of the first active layer ACT1 from the bottom of the first active layer ACT1, and thus, the operating characteristics of the first transistor T1 may be stabilized.

The barrier layer 121 may be located on the lower conductive layer BCDL. The barrier layer 121 may protect the circuit elements of the backplane layer 120 and the light emitting elements LE on the backplane layer 120 from moisture permeating through the substrate 110 that may be susceptible to moisture permeation. In an embodiment, the barrier layer 121 may be formed as a plurality of inorganic insulating layers.

The circuit elements of the backplane layer 120 may be located on the barrier layer 121. For example, the pixel transistors PXT, the storage capacitor Cst, and the boosting capacitor Cbst included in the pixel circuit PXC of each of the sub-pixels SPX may be located on the barrier layer 121. Additionally, wires of the backplane layer 120 may be located on the barrier layer 121. For example, signal lines and power lines electrically connected to the sub-pixels SPX may be located on the barrier layer 121.

FIG. 8 shows, as an example of the circuit elements included in the backplane layer 120, the first transistor T1, the third transistor T3, the fourth transistor T4, the fifth transistor T5, the storage capacitor Cst, and the boosting capacitor Cbst that are included in the first sub-pixel SPX1. Further, FIG. 8 shows, as an example of the wires included in the backplane layer 120, the write scan line GWL, the first and second emission control lines EL1 and EL2, the first power line VDL, and the third power line VIL. Each of other wires may include at least one wiring layer included in at least one conductive layer included in the backplane layer 120, and may be formed as a single-layer or multi-layered wire.

In an embodiment, each of the pixel circuits PXC may include first type transistors and second type transistors. The first type transistors and the second type transistors may be located in different layers from each other within the backplane layer 120. For example, as shown in FIG. 4, each of the pixel circuits PXC may include the first, second, fifth, sixth, seventh, and eighth P-type transistors T1, T2, T5, T6, T7, and T8, and the third and fourth N-type transistors T3 and T4. The active layers included in the first, second, fifth, sixth, seventh, and eighth transistors T1, T2, T5, T6, T7, and T8, and the active layers included in the third and fourth transistors T3 and T4 may be formed in patterns of different semiconductor layers from each other. Further, the gate electrodes included in the first, second, fifth, sixth, seventh, and eighth transistors T1, T2, T5, T6, T7, and T8, and the gate electrodes included in the third and fourth transistors T3 and T4 may be formed in patterns of different conductive layers from each other.

The first semiconductor layer SCL1 (also referred to as a "first semiconductor pattern layer") may be located on the barrier layer 121. The first semiconductor layer SCL1 may include an active layer of each of the first type transistors. For example, the first semiconductor layer SCL1 may include the first active layer ACT1 included in the first transistor T1, a fifth active layer ACT5 included in the fifth transistor T5, and second, sixth, seventh, and eighth active layers included in the second, sixth, seventh, and eighth transistors T2, T6, T7, and T8. In an embodiment, the patterns (e.g., the first and fifth active layers ACT1 and ACT5, and the second, sixth, seventh, and eighth active layers of each sub-pixel SPX) of the first semiconductor layer SCL1 included in one sub-pixel SPX may be formed integrally with each other, but the present disclosure is not limited thereto.

The patterns of the first semiconductor layer SCL1 may include a first semiconductor material. In an embodiment, the first semiconductor material may be polycrystalline silicon (e.g., a low temperature polycrystalline silicon), but the present disclosure is not limited thereto. For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or another suitable oxide semiconductor) or monocrystalline silicon.

The first insulating layer 122 may be located on the first semiconductor layer SCL1. The first insulating layer 122 may include at least one insulating material (e.g., silicon nitride (SiNx), silicon oxide (SiOx), silicon oxynitride (SiON), titanium oxide (TiOx), aluminum oxide (AlOx), or another suitable inorganic insulating material), and may be formed as a single layer or multiple layers.

The first gate conductive layer GCDL1 may be located on the first insulating layer 122. The first gate conductive layer GCDL1 may include a gate electrode of each of the first type transistors. For example, the first gate conductive layer GCDL1 may include the first gate electrode GE1 included in the first transistor T1, a fifth gate electrode GE5 included in the fifth transistor T5, and second, sixth, seventh, and eighth gate electrodes included in the second, sixth, seventh, and eighth transistors T2, T6, T7, and T8.

The first gate conductive layer GCDL1 may further include at least one conductive pattern and/or wire. For example, the first gate conductive layer GCDL1 may further include a first capacitor electrode SCE1 of the storage capacitor Cst, a first electrode BCE1 of the boosting capacitor Cbst, and the write scan line GWL. In an embodiment, the first gate electrode GE1 of each pixel circuit PXC and the first capacitor electrode SCE1 of the storage capacitor Cst may be formed integrally with each other, and the first electrode BCE1 of the boosting capacitor Cbst of each pixel circuit PXC and the write scan line GWL connected to the pixel circuit PXC may be formed integrally with each other. In an embodiment, the first gate conductive layer GCDL1 may further include the bias scan line GBL of FIG. 4.

The second insulating layer 123 may be located on the first gate conductive layer GCDL1. The second insulating layer 123 may contain at least one insulating material (e.g., an inorganic insulating material), and may be formed as a single layer or multiple layers.

The second gate conductive layer GCDL2 may be located on the second insulating layer 123. The second gate conductive layer GCDL2 may include the second capacitor electrode SCE2 of the storage capacitor Cst. The first capacitor electrode SCE1 and the second capacitor electrode SCE2 of the storage capacitor Cst may overlap with each other with the second insulating layer 123 interposed between the first capacitor electrode SCE1 and the second capacitor electrode SCE2.

The second gate conductive layer GCDL2 may further include at least one conductive pattern and/or wire. For example, the second gate conductive layer GCDL2 may further include a first blocking pattern LBP1 and a second blocking pattern LBP2. The first blocking pattern LBP1 and the second blocking pattern LBP2 may be located under a channel region of a third active layer ACT3 (e.g., a part of the third active layer ACT3 that overlaps with the third gate electrode GE3) and a channel region of a fourth active layer ACT4 (e.g., a part of the fourth active layer ACT4 that overlaps with the fourth gate electrode GE4), respectively. Accordingly, light may be blocked from being incident on the channel regions of the third active layer ACT3 and the fourth active layer ACT4 from the bottom of the third active layer ACT3 and the fourth active layer ACT4, and thus, the operating characteristics of the third transistor T3 and the fourth transistor T4 may be stabilized. In an embodiment, the second gate conductive layer GCDL2 may further include the fourth power line VAIL of FIG. 4.

The third insulating layer 124 may be located on the second gate conductive layer GCDL2. The third insulating layer 124 may contain at least one insulating material (e.g., an inorganic insulating material), and may be formed as a single layer or multiple layers.

The second semiconductor layer SCL2 (also referred to as a "second semiconductor pattern layer") may be located on the third insulating layer 124. The second semiconductor layer SCL2 may include the active layer of each of the second type transistors. For example, the second semiconductor layer SCL2 may include the third active layer ACT3 included in the third transistor T3 and the fourth active layer ACT4 included in the fourth transistor T4. In an embodiment, the patterns (e.g., the third and fourth active layers ACT3 and ACT4 of each sub-pixel SPX) of the second semiconductor layer SCL2 included in one sub-pixel SPX may be formed integrally with each other, but the present disclosure is not limited thereto. In an embodiment, the second semiconductor layer SCL2 may further include the second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 may include a second semiconductor material. In an embodiment, the second semiconductor material may be an oxide semiconductor, but the present disclosure is not limited thereto. For example, the second semiconductor material may be polycrystalline silicon or monocrystalline silicon.

The fourth insulating layer 125 may be located on the second semiconductor layer SCL2. The fourth insulating layer 125 may contain at least one insulating material (e.g., an inorganic insulating material), and may be formed as a single layer or multiple layers.

The third gate conductive layer GCDL3 may be located on the fourth insulating layer 125. The third gate conductive layer GCDL3 may include a gate electrode of each of the second type transistors. For example, the third gate conductive layer GCDL3 may include the third gate electrode GE3 included in the third transistor T3 and the fourth gate electrode GE4 included in the fourth transistor T4. The third gate conductive layer GCDL3 may further include at least one conductive pattern and/or wire. For example, the third gate conductive layer GCDL3 may further include at least one of the initialization scan line GIL, the control scan line GCL, or the fifth power line VOBL.

The fifth insulating layer 126 may be located on the third gate conductive layer GCDL3. The fifth insulating layer 126 may contain at least one insulating material (e.g., an inorganic insulating material), and may be formed as a single layer or multiple layers.

The first source-drain conductive layer SCDL1 may be located on the fifth insulating layer 126. The first source-drain conductive layer SCDL1 may include at least one electrode, a conductive pattern, and/or a wire. For example, the first source-drain conductive layer SCDL1 may include first, second, and third connection patterns CNE1, CNE2, and CNE3, the first and second emission control lines EL1 and EL2, and the third power line VIL.

The first connection pattern CNE1 may be electrically connected to the fifth active layer ACT5, the second capacitor electrode SCE2 of the storage capacitor Cst, and the first power line VDL through at least one contact hole or via hole. The second connection pattern CNE2 may be electrically connected to the first active layer ACT1 and the third active layer ACT3 through at least one contact hole. The third connection pattern CNE3 may be electrically connected to the third active layer ACT3 and the fourth active layer ACT4 through at least one contact hole. The third connection pattern CNE3 may be electrically connected to the first gate electrode GE1 and the first capacitor electrode SCE1 of the storage capacitor Cst through at least one contact hole in an area of another view. In an embodiment, the first source-drain conductive layer SCDL1 may further include an additional connection pattern for appropriately connecting the circuit elements of each sub-pixel SPX to one another.

The first emission control line EL1 may be electrically connected to the fifth gate electrode GE5 and the sixth gate electrode of the first sub-pixel SPX1 through at least one contact hole in an area of another view. The second emission control line EL2 may be electrically connected to the fifth and sixth gate electrodes of the second and third sub-pixels SPX2 and SPX3 through at least one contact hole in an area of another view. The third power line VIL may be electrically connected to the fourth active layer ACT4 through at least one contact hole.

The sixth insulating layer 127 may be located on the first source-drain conductive layer SCDL1. The sixth insulating layer 127 may include at least one insulating material (e.g., an acrylic resin, an epoxy resin, a phenolic resin, a polyamide resin, a polyimide resin, or another suitable organic insulating material), and may be formed as a single layer or multiple layers.

The second source-drain conductive layer SCDL2 may be located on the sixth insulating layer 127. The second source-drain conductive layer SCDL2 may include at least one electrode, a conductive pattern, and/or a wire. For example, the second source-drain conductive layer SCDL2 may include the first power line VDL.

In an embodiment, the first power line VDL may extend in or substantially in the second direction DR2 in the display area DA, and may be commonly connected to the sub-pixels SPX arranged continuously and/or sequentially along the second direction DR2. The first power line VDL illustrated as two separated patterns in FIG. 9 may be one or substantially one integral wire. The first power line VDL may be electrically connected to the first connection pattern CNE1 through the first via hole VH1 (e.g., a contact hole). The first via hole VH1, which is an opening formed in (e.g., penetrating ) the sixth insulating layer 127 for contact between the first connection pattern CNE1 and the first power line VDL, may be a kind of contact hole. In an embodiment, the first power line VDL may overlap with the channel regions of the first active layer ACT1, the third active layer ACT3, and the fourth active layer ACT4. Accordingly, light may be prevented or substantially prevented from being incident on the channel regions of the first active layer ACT1, the third active layer ACT3, and the fourth active layer ACT4 from the top of the first active layer ACT1, the third active layer ACT3, and the fourth active layer ACT4, and thus, the operating characteristics of the first transistor T1, the third transistor T3, and the fourth transistor T4 may be stabilized.

In an embodiment, the second source-drain conductive layer SCDL2 may further include the data lines DL of FIGS. 3 and 4. Further, the second source-drain conductive layer SCDL2 may further include the connection patterns CNP (e.g., the anode connection patterns of the sub-pixels SPX) of FIGS. 6 and 7. The connection pattern CNP of each sub-pixel SPX may be electrically connected between the pixel electrode PXE and the pixel circuit PXC of a corresponding sub-pixel SPX. For example, the connection pattern CNP of each sub-pixel SPX may be electrically connected to the sixth and seventh active layers of the corresponding sub-pixel SPX through at least one contact hole and/or at least one other connection pattern, and may be electrically connected to the pixel electrode PXE of the corresponding sub-pixel SPX through the anode contact hole ANH of FIGS. 6 and 7.

In an embodiment, the second source-drain conductive layer SCDL2 may further include at least one wire (e.g., a part of the at least one wire) and/or the pad PD located in the non-display area NDA and/or the sub-region SBA. For example, the second source-drain conductive layer SCDL2 may further include the second wiring layer BLI2 of the power bus line BLI illustrated in FIGS. 6 and 7, and the pads PD (e.g., first pad layers of the pads PD) located in the pad area PA of FIG. 2. Further, the second source-drain conductive layer SCDL2 may further include other wires (e.g., at least one signal line or power line PL respectively electrically connected to the first scan driver SDC1 and the second scan driver SDC2, or the sub-pixels SPX) located in the non-display area NDA of FIG. 2.

The seventh insulating layer 128 may be located on the second source-drain conductive layer SCDL2. The seventh insulating layer 128 may contain at least one insulating material (e.g., an organic insulating material), and may be formed as a single layer or multiple layers.

The patterns included in each of the conductive layers of the backplane layer 120 may contain at least one conductive material. For example, the electrodes, the conductive patterns, and/or the wires included in each of the lower conductive layer BCDL, the first gate conductive layer GCDL1, the second gate conductive layer GCDL2, the third gate conductive layer GCDL3, the first source-drain conductive layer SCDL1, and the second source-drain conductive layer SCDL2 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), another suitable metal, a suitable alloy thereof, or another suitable conductive material. In an embodiment, the electrodes, the conductive patterns, and/or the wires located in the same conductive layer as each other may be concurrently (e.g., simultaneously or substantially simultaneously) formed with each other using the same conductive material. At least two conductive layers of the conductive layers of the backplane layer 120 may include the same conductive material as each other, or may include different conductive materials from each other.

In an embodiment, the patterns included in each of the conductive layers of the backplane layer 120 may have a single-layer or multi-layered structure. For example, each of the electrodes, conductive patterns, and/or wires included in each of the lower conductive layer BCDL, the first gate conductive layer GCDL1, the second gate conductive layer GCDL2, the third gate conductive layer GCDL3, the first source-drain conductive layer SCDL1, and the second source-drain conductive layer SCDL2 may have a single-layer or multi-layered structure. At least two of the conductive layers of the backplane layer 120 may have the same cross-sectional structure as each other, or different cross-sectional structures from each other.

In an embodiment, the patterns of the second source-drain conductive layer SCDL2 may include a metal (e.g., at least one of molybdenum (Mo), aluminum (Al), chromium (Cr), gold (Au), titanium (Ti), nickel (Ni), neodymium (Nd), copper (Cu), another suitable metal, or a suitable alloy thereof), and may have a single-layer or multi-layered structure. For example, the electrodes, conductive patterns, and/or wires included in the second source-drain conductive layer SCDL2 may be a low-resistance pattern formed in a three-layered structure (Ti/Al/Ti) of titanium (Ti), aluminum (Al), and titanium (Ti). As another example, the patterns of the second source-drain conductive layer SCDL2 may include other suitable low-resistance materials and/or structures. When the resistance of the patterns included in the second source-drain conductive layer SCDL2 is reduced, the resistance of the conductive patterns and/or wires located on a current path through which the driving current of each of the sub-pixels SPX flows may be reduced. Accordingly, the image quality of the display device 1 may become uniform, and a power consumption may be improved.

The light emitting element layer 130 may be located on the seventh insulating layer 128. The light emitting element layer 130 may include the pixel electrodes PXE, the light emitting elements LE, and the common electrode CE included in the sub-pixels SPX. Additionally, the light emitting element layer 130 may further include insulating layers. In an embodiment, the insulating layers of the light emitting element layer 130 may include eighth and ninth insulating layers 132 and 134, and a first capping layer 136.

A pixel electrode layer PCDL including the pixel electrodes PXE of the sub-pixels SPX may be located on the seventh insulating layer 128. For example, the pixel electrode layer PCDL may include the first pixel electrode PXE1, the second pixel electrode PXE2, and the third pixel electrode PXE3. In an embodiment, the light emitting element LE may be a flip-chip kind micro LED. The flip-chip kind micro LED refers to an LED in which first and second contact electrodes CTE1 and CTE2 are formed on one surface (e.g., the bottom surface) of the light emitting element LE. When the light emitting element LE is a flip-chip kind micro LED, the pixel electrode layer PCDL may further include the common electrode CE. For example, the pixel electrodes PXE and the common electrode CE of the sub-pixels SPX may be located in the same layer as each other, and may be concurrently (e.g., simultaneously or substantially simultaneously) formed with each other using the same conductive material. Accordingly, the pixel electrodes PXE and the common electrode CE may have the same cross-sectional structure as each other. FIG. 8 illustrates the common electrode CE and the first pixel electrode PXE1 of the first sub-pixel SPX1 among the patterns of the pixel electrode layer PCDL.

The first pixel electrode PXE1 of the first sub-pixel SPX1 may be electrically connected to the pixel circuit PXC of the first sub-pixel SPX1 through the first anode contact hole ANH1 and/or the connection pattern CNP of FIGS. 6 and 7. The second pixel electrode PXE2 of the second sub-pixel SPX2 may be electrically connected to the pixel circuit PXC of the second sub-pixel SPX2 through the second anode contact hole ANH2 and/or the connection pattern CNP of FIGS. 6 and 7. The third pixel electrode PXE3 of the third sub-pixel SPX3 may be electrically connected to the pixel circuit PXC of the third sub-pixel SPX3 through the third anode contact hole ANH3 and/or the connection pattern CNP of FIGS. 6 and 7. The pixel circuits PXC of the first sub-pixel SPX1, the second sub-pixel SPX2, and the third sub-pixel SPX3 may control voltages applied to the first pixel electrode PXE1, the second pixel electrode PXE2, and the third pixel electrode PXE3, respectively.

The patterns (e.g., the pixel electrodes PXE and the common electrode CE) of the pixel electrode layer PCDL may include the same conductive material as each other. In an embodiment, the pixel electrodes PXE and the common electrode CE may include the reflective layer RFL including a suitable material (e.g., silver (Ag), aluminum (Al), or another suitable metal having a high light reflectivity) for reflecting light emitted from the light emitting element LE. For example, the pixel electrodes PXE and the common electrode CE may each have a single-layer or multi-layered structure including the reflective layer RFL. The reflective layer RFL included in the pixel electrode PXE of each of the sub-pixels SPX may be located under a part of the light emitting element LE located in each sub-pixel SPX, and the reflective layer RFL included in the common electrode CE of each of the sub-pixels SPX may be located under another part of the light emitting element LE located in each sub-pixel SPX. The light propagating toward the bottom of the light emitting element LE may be appropriately reflected by the respective reflective layers RFL included in the common electrode CE and the pixel electrode PXE of each of the sub-pixels SPX.

In consideration of the light reflectivity by the pixel electrodes PXE and the common electrode CE, and the conductivity and reliability of the pixel electrodes PXE and the common electrode CE, the pixel electrodes PXE and the common electrode CE may include an appropriate material, and may be formed to have an appropriate structure and/or thickness. In an embodiment, each of the pixel electrodes PXE and the common electrode CE may have a multi-layered structure including at least one conductive layer and/or capping layer located on at least one surface of the reflective layer RFL. For example, the pixel electrodes PXE and the common electrode CE may each further include a lower capping layer CPL1 located directly under the reflective layer RFL and covering the bottom surface of the reflective layer RFL, and an upper capping layer CPL2 located directly above the reflective layer RFL and covering the top surface of the reflective layer RFL. In an embodiment, the reflective layer RFL may include silver (Ag), and the lower capping layer CPL1 and the upper capping layer CPL2 may include indium-tin oxide (ITO). For example, the pixel electrodes PXE and the common electrode CE may each have a three-layered structure (ITO/Ag/ITO) of indium-tin oxide (ITO), silver (Ag), and indium-tin oxide (ITO). Accordingly, the light reflectivity, conductivity, and reliability of the pixel electrodes PXE and the common electrode CE may be secured.

The eighth insulating layer 132 may be located on the pixel electrode layer PCDL. The eighth insulating layer 132 may be an adhesive layer that temporarily fixes or adheres the light emitting elements LE to prevent or substantially prevent the light emitting elements LE from tilting and falling over or tipping over during a process of transferring the light emitting elements LE to the display panel 100. For example, the eighth insulating layer 132 may be a film for temporarily adhering the light emitting elements LE onto each of the pixel electrodes PXE and the common electrode CE. To facilitate a temporary adhesion, the thickness of the eighth insulating layer 132 may be greater than the thickness of each of the pixel electrodes PXE and the common electrode CE, and may be greater than the thickness of each of the first and second contact electrodes CTE1 and CTE2 of the light emitting elements LE. The eighth insulating layer 132 may also be referred to as an "adhesive layer."

The eighth insulating layer 132 may cover a part of the pixel electrode PXE and a part of the common electrode CE, including a portion overlapping with each light emitting element LE, and may expose other parts of the common electrode CE and the pixel electrode PXE. For example, the eighth insulating layer 132 may cover the pixel electrode PXE and the common electrode CE under the light emitting element LE, and may be opened at portions corresponding to the first connection hole BH1 and the second connection hole BH2 to partially expose the top surfaces of the common electrode CE and the pixel electrode PXE.

Although it is illustrated in FIG. 8 that the eighth insulating layer 132 is entirely located in the display area DA or the sub-pixel area, the present disclosure is not limited thereto. For example, the eighth insulating layer 132 may be located only on parts of the pixel electrodes PXE and the common electrode CE that overlap with the light emitting elements LE, and may not cover other parts of the pixel electrodes PXE and the common electrode CE. As another example, the eighth insulating layer 132 may be separately located in each of the sub-pixels SPX.

The eighth insulating layer 132 may include at least one insulating material, for example, such as an organic insulating material. For example, the eighth insulating layer 132 may be a photosensitive organic layer, such as a photoresist. As another example, the eighth insulating layer 132 may include an acryl resin, an epoxy resin, a phenolic resin, a polyamide resin, a polyimide resin, or the like.

Although it is illustrated in FIG. 8 that the eighth insulating layer 132 is located with an overall uniform thickness or height, the present disclosure is not limited thereto. For example, the eighth insulating layer 132 may have a lower height in portions where the light emitting elements LE are located than in other portions. For example, the eighth insulating layer 132 may be pressed by a pressure applied during a process of locating the light emitting elements LE on the eighth insulating layer 132, so that the height or thickness of the eighth insulating layer 132 may be partially reduced.

The light emitting elements LE may be located on the eighth insulating layer 132. The first light emitting element LE1 may be located on the first pixel electrode PXE1 of the first sub-pixel SPX1 and the common electrode CE. The second light emitting element LE2 may be located on the second pixel electrode PXE2 of the second sub-pixel SPX2 and the common electrode CE. The third light emitting element LE3 may be located on the third pixel electrode PXE3 of the third sub-pixel SPX3 and the common electrode CE.

In an embodiment, each of the light emitting elements LE may be a micro LED including an inorganic material. For example, each of the light emitting elements LE may include an inorganic material, such as gallium nitride (GaN), and the length in the first direction DR1, the length in the second direction DR2, and the length in the third direction DR3 of each of the light emitting elements LE may each be several µm to several hundred µm. For example, the length in the first direction DR1, the length in the second direction DR2, and the length in the third direction DR3 of each of the light emitting elements LE may each be approximately 100 µm or less.

The light emitting elements LE may be formed by being grown on a semiconductor substrate, such as a silicon substrate or a sapphire substrate. The light emitting elements LE may be transferred directly from the semiconductor substrate onto the pixel electrodes PXE and the common electrode CE of the display panel 100. As another example, the light emitting elements LE may be transferred onto the common electrode CE and the pixel electrodes PXE of the display panel 100 through an electrostatic method using an electrostatic head, or a stamping method using an elastic polymer material such as PDMS or silicon as a transfer substrate.

The light emitting element LE may include a conductive layer E1, a semiconductor stack STC, the first and second contact electrodes CTE1 and CTE2, and a protective film PRL. The semiconductor stack STC may include a first semiconductor layer SEM1, an active layer MQW (e.g., a light emitting layer), and a second semiconductor layer SEM2 sequentially located in the third direction DR3. In an embodiment, the semiconductor stack STC may further include a third semiconductor layer SEM3 located on the second semiconductor layer SEM2.

The conductive layer E1 may be located on the bottom surface of the first semiconductor layer SEM1. FIG. 10 illustrates that the conductive layer E1 covers the entire bottom surface of the first semiconductor layer SEM1, but the present disclosure is not limited thereto. For example, the conductive layer E1 may be located on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), copper (Cu), or a suitable transparent conductive material, such as a metal oxide.

The first semiconductor layer SEM1 may be located on the conductive layer E1. The first semiconductor layer SEM1 may include a semiconductor material doped with a first conductivity type dopant, such as magnesium (Mg), zinc (Zn), calcium (Ca), strontium (Sr), or barium (Ba), for example, such as gallium nitride (GaN).

The active layer MQW may be located on the first semiconductor layer SEM1. The active layer MQW may include the same semiconductor material as that of the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least one of gallium nitride (GaN), indium gallium nitride (InGaN), or aluminum gallium nitride (AlGaN). The active layer MQW may emit light by recombination of electron-hole pairs according to an electrical signal applied through the first semiconductor layer SEM1 and the second semiconductor layer SEM2.

The active layer MQW may include a suitable material having a single or multiple quantum well structure. When the active layer MQW contains a material having a multiple quantum well structure, the active layer MQW may have a structure in which a plurality of well layers and barrier layers are alternately stacked. In this case, the well layer may include InGaN, and the barrier layer may include GaN or AlGaN, but the present disclosure is not limited thereto. As another example, the active layer MQW may have a structure in which semiconductor materials having a large band gap energy and semiconductor materials having a small band gap energy are alternately stacked, and may include other group III to V semiconductor materials according to the wavelength band of the emitted light.

When the active layer MQW includes indium gallium nitride (InGaN), the color of emitted light may vary depending on the content of indium (In). For example, as the content of indium (In) increases, the wavelength band of the light emitted by the active layer MQW may shift to the red wavelength band, and as the content of indium (In) decreases, the wavelength band of the light emitted by the active layer MQW may shift to the blue wavelength band.

The second semiconductor layer SEM2 may be located on the active layer MQW. The second semiconductor layer SEM2 may be a semiconductor material layer doped with a second conductivity type dopant, such as silicon (Si), germanium (Ge), or tin (Sn), for example, such as gallium nitride (GaN).

The third semiconductor layer SEM3 may be located on the second semiconductor layer SEM2. The third semiconductor layer SEM3 may be a semiconductor material layer having an n-type dopant lower than a critical value (e.g., a selected or predetermined critical value), and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN) having an n-type dopant lower than a threshold value (e.g., a selected or predetermined threshold value).

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with a p-type Mg. The electron blocking layer may be omitted as needed or desired.

A superlattice layer may be located between the active layer MQW and the second semiconductor layer SEM2. The superlattice layer may be a layer for relieving a stress between the second semiconductor layer SEM2 and the active layer MQW. For example, the superlattice layer may include InGaN or GaN. The superlattice layer may be omitted as needed or desired.

The protective film PRL may be located on the side surface of the first semiconductor layer SEM1, the side surface of the active layer MQW, and the side surface of the second semiconductor layer SEM2. In an embodiment, the protective film PRL may also be located on the side surface of the third semiconductor layer SEM3. The protective film PRL may be a film for protecting the side surface of the light emitting element LE. The protective film PRL may include an inorganic material, for example, such as silicon nitride (SiNx), silicon oxide (SiOx), silicon oxynitride (SiON), titanium oxide (TiOx), aluminum oxide (AlOx), or another suitable inorganic insulating material.

A hole LEH that penetrates the conductive layer E1, the first semiconductor layer SEM1, and the active layer MQW of the light emitting element LE to expose the second semiconductor layer SEM2 may be formed. The hole LEH may have a circular planar shape, but the shape of the hole LEH is not limited thereto. For example, the hole LEH may have a suitable planar shape, such as an elliptical shape or a polygonal shape, for example, such as a quadrilateral shape.

The protective film PRL may be located on the sidewall of the conductive layer E1 exposed in the hole LEH, the sidewall of the first semiconductor layer SEM1, and the sidewall of the active layer MQW. The protective film PRL may not cover the second semiconductor layer SEM2 at the hole LEH. Accordingly, the second semiconductor layer SEM2 may be exposed without being covered by the protective film PRL.

The first contact electrode CTE1 may be located on at least one side surface of the semiconductor stack STC, and on at least one side surface and the bottom surface of the conductive layer E1. The first contact electrode CTE1 may be located on the bottom surface of the conductive layer E1 exposed without being covered by the protective film PRL. Accordingly, the first contact electrode CTE1 may be electrically connected to the conductive layer E1.

The second contact electrode CTE2 may be located on at least one side surface of the semiconductor stack STC, and on at least one side surface and the bottom surface of the conductive layer E1. In this case, the first contact electrode CTE1 may be located on the first side surface of the semiconductor stack STC and the first side surface of the conductive layer E1, while the second contact electrode CTE2 may be located on the second side surface of the semiconductor stack STC and the second side surface of the conductive layer E1.

The second contact electrode CTE2 may be located on the protective film PRL located in the hole LEH and the second semiconductor layer SEM2 exposed without being covered by the protective film PRL in the hole LEH. Accordingly, the second contact electrode CTE2 may be electrically connected to the second semiconductor layer SEM2 in the hole LEH.

In an embodiment, each of the first contact electrode CTE1 and the second contact electrode CTE2 may be located on three side surfaces of the semiconductor stack STC. For example, when the semiconductor stack STC includes first to fourth side surfaces, the first contact electrode CTE1 may be located on the first side surface, the second side surface, and the third side surface, and the second contact electrode CTE2 may be located on the second side surface, the third side surface, and the fourth side surface.

Each of the first contact electrode CTE1 and the second contact electrode CTE2 may include at least one conductive material, for example, such as one of molybdenum (Mo), aluminum (Al), chromium (Cr), gold (Au), titanium (Ti), nickel (Ni), neodymium (Nd), and/or copper (Cu). In an embodiment, in order to increase the reflectivity, the first contact electrode CTE1 and the second contact electrode CTE2 may be formed in a two-layered structure (Cr/Au) of chromium (Cr) and gold (Au), a three-layered structure (Ti/Al/Ti) of titanium (Ti), aluminum (Al), and titanium (Ti), or a three-layered structure (ITO/Ag/ITO) of indium-tin oxide (ITO), silver (Ag), and indium-tin oxide (ITO).

When each of the first contact electrode CTE1 and the second contact electrode CTE2 includes a metal having a high reflectivity, light emitted from the active layer MQW of the light emitting element LE, which propagates in the lateral direction of the light emitting element LE, may be reflected by the first contact electrode CTE1 and the second contact electrode CTE2 and emitted to the top surface of the light emitting element LE. Accordingly, because light loss from the light emitting element LE may be reduced, the light efficiency of the light emitting element LE may be increased. To increase the light efficiency of the light emitting element LE, the first contact electrode CTE1 and the second contact electrode CTE2 may be located to cover most of the side surface of the semiconductor stack STC.

The first contact electrode CTE1 may be in contact with the first connection electrode BE1 on the pixel electrode PXE. The second contact electrode CTE2 may be in contact with the second connection electrode BE2 on the common electrode CE.

The first connection electrode BE1 and the second connection electrode BE2 may be located on the eighth insulating layer 132.

The first connection electrode BE1 connects a part of the light emitting element LE to the pixel electrode PXE. For example, the first connection electrode BE1 of the first sub-pixel SPX1 may connect the first contact electrode CTE1 of the first light emitting element LE1 and the first pixel electrode PXE1 to each other. The first connection electrode BE1 of the second sub-pixel SPX2 may connect the first contact electrode CTE1 of the second light emitting element LE2 to the second pixel electrode PXE2. The first connection electrode BE1 of the third sub-pixel SPX3 may connect the first contact electrode CTE1 of the third light emitting element LE3 to the third pixel electrode PXE3.

In an embodiment, the first connection electrode BE1 may be in contact with a part (e.g., at least one side surface of the light emitting element LE including the side surface on which the first contact electrode CTE1 is located) of the light emitting element LE on a part of the pixel electrode PXE and the eighth insulating layer 132, and may be in contact with the pixel electrode PXE on another part (e.g., a part that is not covered by the eighth insulating layer 132 due to the first connection hole BH1) of the pixel electrode PXE. For example, the first connection electrode BE1 may be electrically connected to each of the pixel electrodes PXE through the first connection hole BH1 penetrating the eighth insulating layer 132. In another embodiment, when the eighth insulating layer 132 is located only on a portion of the pixel electrode PXE overlapping with the light emitting element LE, the first connection hole BH1 may be unnecessary or omitted. For example, the first connection electrode BE1 may be located directly on the pixel electrode PXE exposed around the light emitting element LE.

The second connection electrode BE2 connects another portion of the light emitting element LE to the common electrode CE. For example, the second connection electrode BE2 of the first sub-pixel SPX1 may connect the second contact electrode CTE2 of the first light emitting element LE1 and the common electrode CE to each other. The second connection electrode BE2 of the second sub-pixel SPX2 may connect the second contact electrode CTE2 of the second light emitting element LE2 and the common electrode CE to each other. The second connection electrode BE2 of the third sub-pixel SPX3 may connect the second contact electrode CTE2 of the third light emitting element LE3 and the common electrode CE to each other.

In an embodiment, the second connection electrode BE2 may be in contact with another part (e.g., at least one side surface of the light emitting element LE including the side surface on which the second contact electrode CTE2 is located) of the light emitting element LE on a part of the common electrode CE and the eighth insulating layer 132, and may be in contact with the common electrode CE on another part (e.g., a part that is not covered by the eighth insulating layer 132 due to the second connection hole BH2) of the common electrode CE. For example, the second connection electrode BE2 may be electrically connected to the common electrode CE through the second connection hole BH2 penetrating the eighth insulating layer 132. In another embodiment, when the eighth insulating layer 132 is located only on a portion of the common electrode CE overlapping with the light emitting element LE, the second connection hole BH2 may be unnecessary or omitted. For example, the second connection electrode BE2 may be located directly on the common electrode CE exposed around the light emitting element LE.

Each of the first connection electrode BE1 and the second connection electrode BE2 may include at least one conductive material, for example, such as one of molybdenum (Mo), aluminum (Al), chromium (Cr), gold (Au), titanium (Ti), nickel (Ni), neodymium (Nd), and/or copper (Cu). As another example, each of the first connection electrode BE1 and the second connection electrode BE2 may include a transparent conductive material (e.g., a transparent conductive oxide (TCO)), such as indium tin oxide (ITO) or indium zinc oxide (IZO). In an embodiment, the first connection electrode BE1 and the second connection electrode BE2 are formed using a transparent conductive oxide, so that the reliability of the display device 1 may be increased.

The conductive layer E1 of the light emitting element LE may be in contact with and/or connected to the first contact electrode CTE1, and may be electrically connected to the first connection electrode BE1 through the first contact electrode CTE1. The second semiconductor layer SEM2 of the light emitting element LE may be in contact with and/or connected to the second contact electrode CTE2 formed in the hole LEH, and may be electrically connected to the second connection electrode BE2 through the second contact electrode CTE2.

The ninth insulating layer 134 may be located on the eighth insulating layer 132. In an embodiment, the ninth insulating layer 134 may be formed to have a height less than or equal to the height of the light emitting elements LE, and may partially or entirely cover the side surfaces of the light emitting elements LE. The top surface of each of the light emitting elements LE may be exposed without being covered by the ninth insulating layer 134.

Further, the ninth insulating layer 134 may cover at least a part of the first and second connection electrodes BE1 and BE2. For example, as illustrated in FIG. 10, the ninth insulating layer 134 may be formed to have a height greater than or equal to the maximum height of the first and second connection electrodes BE1 and BE2 to completely cover the first and second connection electrodes BE1 and BE2, but the present disclosure is not limited thereto.

The ninth insulating layer 134 may include at least one insulating material, for example, such as an organic insulating material. For example, the ninth insulating layer 134 may be formed as an organic insulating layer, such as an acryl resin, an epoxy resin, a phenolic resin, a polyamide resin, a polyimide resin, and the like. The ninth insulating layer 134 may be formed as a single layer or multiple layers. The ninth insulating layer 134 may flatten or substantially flatten a stepped portion caused by the light emitting elements LE.

The first capping layer 136 may be located on the light emitting elements LE and the ninth insulating layer 134. The first capping layer 136 may include at least one insulating material, for example, such as an inorganic insulating material.

The optical layer 140 may be located on the first capping layer 136. The optical layer 140 may include a light transmitting layer TPL located in the emission areas EA of the sub-pixels SPX, a light blocking layer BM located in the non-emission area NEA to surround (e.g., around peripheries of) the emission areas EA of the sub-pixels SPX, and color filters (e.g., first, second, and third color filters CF1, CF2, and CF3) corresponding to the emission color of each of the sub-pixels SPX.

Although a structure in which the light blocking layer BM, the second capping layer 142, and the reflective film RF are located on the first capping layer 136, and the light transmitting layer TPL and a third capping layer 144 are located on the second capping layer 142 and the reflective film RF is illustrated in FIG. 8, the present disclosure is not limited thereto. For example, the arrangement order and/or shape of the light blocking layer BM, the reflective film RF, and the light transmitting layer TPL may be variously modified as needed or desired.

The light blocking layer BM may be located on the first capping layer 136. The light blocking layer BM may partition the emission area EA and the non-emission area NEA. The light blocking layer BM may include a light blocking material, such as an organic black pigment or an inorganic black pigment such as carbon black or the like. The light blocking layer BM may include an organic film, such as an acryl resin, an epoxy resin, a phenolic resin, a polyamide resin, a polyimide resin, and the like, but the present disclosure is not limited thereto.

The second capping layer 142 may be located on the first capping layer 136 and the light blocking layer BM. The second capping layer 142 may include at least one insulating material, for example, such as an inorganic insulating material.

The reflective film RF may be located on the light blocking layer BM. For example, the reflective film RF may be located on a part of the second capping layer 142 that covers the side surface of the light blocking layer BM. The reflective film RF may reflect light propagating in a lateral direction from the light transmitting layer TPL. The reflective film RF may include a suitable material having a high light reflectivity, for example, a metal such as aluminum (Al). As another example, the reflective film RF may be formed as a distributed Bragg reflector including inorganic films (e.g., silicon nitride (SiNₓ), silicon nitride oxide (SiON), silicon oxide (SiOₓ), titanium oxide (TiOₓ), or aluminum oxide (AlOₓ)) having different refractive indices from each other, and arranged alternately.

The light transmitting layer TPL may be located in each emission area EA and surrounded (e.g., around a periphery thereof) by the light blocking layer BM. In an embodiment, the light transmitting layer TPL may include a transparent or substantially transparent organic material. For example, the light transmitting layer TPL may be a light transmitting organic film including an epoxy resin, an acrylic resin, a cardo resin, or an imide resin.

In an embodiment, the light emitting element LE may emit light of a color corresponding to the emission color of each sub-pixel SPX, and the light transmitting layer TPL may transmit the light emitted from the light emitting element LE. When the sub-pixels SPX include the light emitting elements LE that emit light corresponding to each emission color, the light emitted from the light emitting elements LE may be utilized more efficiently. For example, it may be possible to prevent or substantially prevent a decrease in the light efficiency of the sub-pixels SPX due to a light conversion. In addition, the color purity of light emitted from the sub-pixels SPX may be increased, and the color reproducibility of the sub-pixels SPX may be increased.

In another embodiment, the light emitting element LE of at least one sub-pixel SPX may emit light of a color different from the emission color of the corresponding sub-pixel SPX, and a wavelength conversion layer including wavelength conversion particles may be located on the light emitting element LE of the at least one sub-pixel SPX. In an embodiment, the wavelength conversion layer may include a base resin constituting the light transmitting layer TPL, and wavelength conversion particles (e.g., quantum dots, quantum rods, fluorescent materials, or phosphorescent materials) dispersed in the light transmitting layer TPL. The wavelength conversion layer may convert light emitted from the light emitting element LE of the corresponding sub-pixel SPX into light of another color. For example, when the first light emitting element LE1 emits blue light and the first sub-pixel SPX1 is a red sub-pixel that emits red light, the wavelength conversion layer including wavelength conversion particles for converting blue light into red light may be located on the first light emitting element LE1. When the sub-pixels SPX include light emitting elements LE that emit light of the same color as each other, a manufacturing efficiency of the light emitting element layer 130 and the display panel 100 including the same may be increased, and manufacturing costs may be reduced.

The third capping layer 144 may be located on the second capping layer 142 and the light transmitting layer TPL. The third capping layer 144 may include at least one insulating material, for example, such as an inorganic insulating material.

A first overcoat layer 146 may be located on the third capping layer 144. In an embodiment, the first overcoat layer 146 may include a light transmitting organic material (e.g., an acrylic resin, an epoxy resin, a phenolic resin, a polyamide resin, or a polyimide resin), and the top surface of the first overcoat layer 146 may be flat or substantially flat. However, the present disclosure is not limited thereto. For example, the first overcoat layer 146 may be an inorganic layer including an inorganic material, and the first overcoat layer 146 may be formed to have a sufficient thickness to include a flat or substantially flat top surface, or may be flattened or substantially flattened through a separate planarization process. Accordingly, the top surface of the first overcoat layer 146 may be flat or substantially flat.

The color filters of the sub-pixels SPX may be located on the first overcoat layer 146. The color filter for selectively transmitting light corresponding to the color (e.g., the wavelength) corresponding to the emission color of the corresponding sub-pixel SPX may be located in the emission area EA of each of the sub-pixels SPX. For example, the first color filter CF1 for selectively transmitting light of the first color may be located in the emission area EA of the first sub-pixel SPX1. The second color filter CF2 for selectively transmitting light of the second color may be located in the emission area EA of the second sub-pixel SPX2. The third color filter CF3 for selectively transmitting light of the third color may be located in the emission area EA of the third sub-pixel SPX3. In an embodiment, the color filters of the sub-pixels SPX may be located to overlap with each other in the non-emission area NEA, thereby forming a light blocking pattern. For example, the first color filter CF1, the second color filter CF2, and the third color filter CF3 respectively located in the first sub-pixel SPX1, the second sub-pixel SPX2, and the third sub-pixel SPX3 may overlap with each other in the non-emission area NEA.

A second overcoat layer 148 may be located on the first color filter CF1, the second color filter CF2, and the third color filter CF3. In an embodiment, the second overcoat layer 148 may include a light transmitting organic material, and the top surface of the second overcoat layer 148 may be flat or substantially flat. However, the present disclosure is not limited thereto. For example, the second overcoat layer 148 according to another embodiment may be an inorganic layer including an inorganic material, and the second overcoat layer 148 may be formed to have a sufficient thickness to include a flat or substantially flat top surface, or may be flattened or substantially flattened through a separate planarization process. Accordingly, the top surface of the second overcoat layer 148 may be flat or substantially flat.

As described above, in some embodiments, the patterns of the pixel electrode layer PCDL located under the light emitting element LE of each of the sub-pixels SPX may be formed as a single-layer or multi-layered pattern including the reflective layer RFL. For example, the common electrode CE and the pixel electrode PXE of each of the sub-pixels SPX may each include the reflective layer RFL, and may further selectively include at least one of the lower capping layer CPL1 and/or the upper capping layer CPL2 respectively covering the bottom surface and the top surface of the reflective layer RFL.

According to some embodiments, the reflectivity of light emitted from the light emitting element LE may be increased, and the light efficiency of the sub-pixel SPX may be improved. For example, the light propagating downward toward the pixel electrode PXE and the common electrode CE among the light emitted from the light emitting element LE may be reflected in an upward direction (e.g., toward the front side of the display panel 100) of the sub-pixel SPX by the pixel electrode PXE and the common electrode CE, so that the light output of the sub-pixel SPX may be increased, and the luminance of the sub-pixel SPX may be increased. Accordingly, the light efficiency of the sub-pixels SPX and the display device 1 including them may be improved.

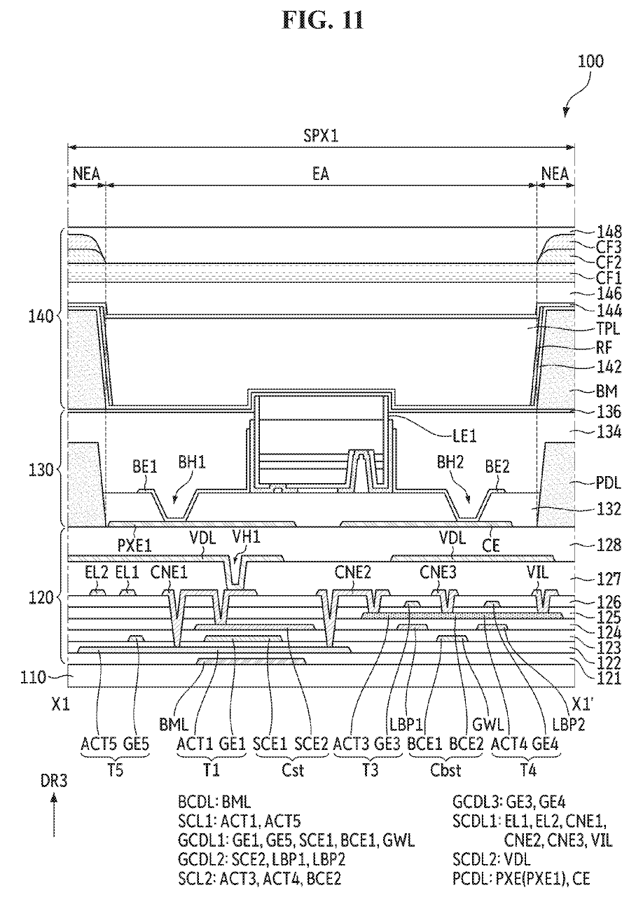

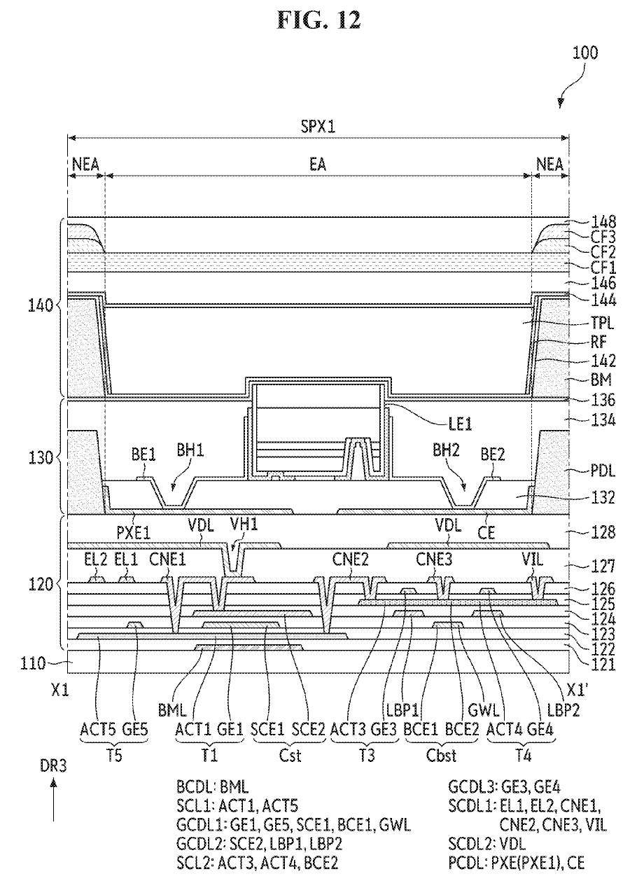

FIG. 11 is a cross-sectional view illustrating a display panel according to an embodiment. FIG. 12 is a cross-sectional view illustrating a display panel according to an embodiment. For example, FIGS. 11 and 12 show different embodiments of the cross-sections of a part of the display panel 100 corresponding to the line X1-X1' in FIG. 7. The embodiments illustrated in FIGS. 11 and 12 may be different from that of FIG. 8, in that the display panel 100 may further include a pixel defining layer PDL.

Referring to FIGS. 11 and 12, the display panel 100 may further include the pixel defining layer PDL (e.g., a bank layer) located in the light emitting element layer 130. The pixel defining layer PDL may be located in the non-emission area NEA, while surrounding (e.g., around a periphery of) the emission area EA. For example, the pixel defining layer PDL may surround (e.g., around a periphery of) the light emitting element LE at a position spaced apart from the light emitting element LE. The pixel defining layer PDL may overlap with the light blocking layer BM in the third direction DR3, and may partition the emission area EA and the non-emission area NEA together with the light blocking layer BM.

In an embodiment, the pixel defining layer PDL may include a light blocking material, such as an inorganic black pigment such as carbon black, or an organic black pigment. The pixel defining layer PDL may include an organic film, such as an acryl resin, an epoxy resin, a phenolic resin, a polyamide resin, a polyimide resin, and the like, but the present disclosure is not limited thereto.

In an embodiment, the pixel electrodes PXE and the common electrode CE may not overlap with the pixel defining layer PDL. For example, as shown in FIG. 11, the pixel electrodes PXE and the common electrode CE may be arranged only inside the emission area EA, and may not overlap with the pixel defining layer PDL in the third direction DR3.

In another embodiment, the pixel electrodes PXE and the common electrode CE may overlap with or be partially located on the pixel defining layer PDL. For example, as shown in FIG. 12, the pixel electrodes PXE and the common electrode CE may expand or extend toward the non-emission area NEA, and an edge portion of each of the pixel electrodes PXE and the common electrode CE may be positioned on a side surface of the pixel defining layer PDL. In an embodiment, the side surface of the pixel defining layer PDL may have a tapered shape that is inclined with respect to the top surface of the substrate 110 or the backplane layer 120. Accordingly, the edge portion of each of the pixel electrodes PXE and the common electrode CE may have a shape that is inclined with respect to the top surface of the substrate 110 or the backplane layer 120 corresponding to the shape of the pixel defining layer PDL.

However, the present disclosure is not limited thereto. For example, in another embodiment, the pixel electrodes PXE and the common electrode CE may overlap with the pixel defining layer PDL, but the edge portions of the pixel electrodes PXE and the common electrode CE may be positioned below the pixel defining layer PDL to be covered with the pixel defining layer PDL.

According to the embodiments illustrated in FIGS. 11 and 12, by locating the pixel defining layer PDL in the non-emission area NEA of the light emitting element layer 130, a boundary between the sub-pixels SPX may be defined more clearly. In addition, an electrical and/or optical interference between adjacent sub-pixels SPX may be more effectively reduced or prevented by the pixel defining layer PDL.

When the edge portions of the pixel electrodes PXE and the common electrode CE are positioned on the side surface of the pixel defining layer PDL as illustrated in the embodiment of FIG. 12, light reflectivity by the pixel electrodes PXE and the common electrode CE may be further increased. Accordingly, the light efficiency of the sub-pixels SPX and the display device 1 including them may be improved more effectively.

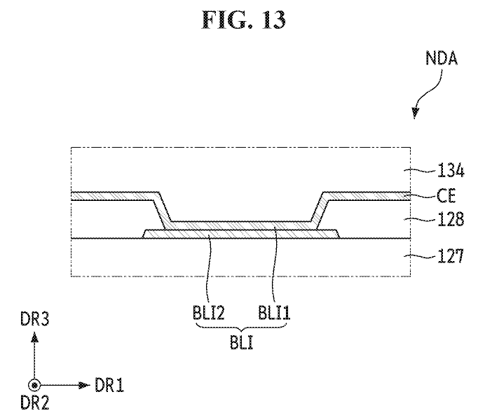

FIG. 13 is a cross-sectional view illustrating a power bus line according to an embodiment. For example, FIG. 13 shows an embodiment of a cross-section of a part of the power bus line BLI shown in FIGS. 6 and 7.

Referring to FIG. 13 in addition to FIGS. 6 to 12, the power bus line BLI may include a first wiring layer BLI1 and a second wiring layer BLI2. In an embodiment, the first wiring layer BLI1 may be formed as a pattern included in the light emitting element layer 130 of the display panel 100 (e.g., the pattern of the pixel electrode layer PCDL), and the second wiring layer BLI2 may be formed as a pattern included in the backplane layer 120 of the display panel 100 (e.g., the pattern of the second source-drain conductive layer SCDL2).

The first wiring layer BLI1 may extend from the common electrode CE. For example, the first wiring layer BLI1 may be formed in a three-layered structure (ITO/Ag/ITO) of indium-tin oxide (ITO), silver (Ag), and indium-tin oxide (ITO). The first wiring layer BLI1 and the common electrode CE may be formed with each other as one body.

The second wiring layer BLI2 may be located below the first wiring layer BLI1. For example, the second wiring layer BLI2 may be located on the sixth insulating layer 127 in the non-display area NDA, and may be in contact with and/or be connected to the first wiring layer BLI1 in a part of the non-display area NDA.

The seventh insulating layer 128 may be located on a part of the second wiring layer BLI2. The seventh insulating layer 128 may be opened to expose another part of the second wiring layer BLI2. For example, the seventh insulating layer 128 may cover an end portion of the second wiring layer BLI2, and may expose another portion (e.g., a central portion) of the second wiring layer BLI2. The first wiring layer BLI1 and the second wiring layer BLI2 may be connected to each other in the opening portion of the seventh insulating layer 128. For example, the bottom surface of the first wiring layer BLI1 may be in contact with the top surface of the second wiring layer BLI2 in the opening portion of the seventh insulating layer 128, so that the first wiring layer BLI1 may be electrically connected to the second wiring layer BLI2.

In an embodiment, the second wiring layer BLI2 may include a low-resistance material. For example, the second wiring layer BLI2 may be formed as a pattern of the second source-drain conductive layer SCDL2, and may be formed in a single-layer or multi-layered pattern including a low-resistance material. For example, the second wiring layer BLI2 may be formed in a three-layered structure (Ti/Al/Ti) of titanium (Ti), aluminum (Al), and titanium (Ti). Accordingly, the resistance of the power bus line BLI may be decreased, and the second driving voltage VSS may be stably transmitted to the sub-pixels SPX of the display area DA.

The patterns of the conductive layer including the second wiring layer BLI2, for example, such as the second source-drain conductive layer SCDL2, may be formed before the patterns of the pixel electrode layer PCDL including the pixel electrodes PXE, the common electrode CE, and the first wiring layer BLI1. Before a process for forming the patterns of the pixel electrode layer PCDL is performed, the seventh insulating layer 128 may be opened in the contact area for connecting the second wiring layer BLI2 to the first wiring layer BLI1. Thus, a part of the top surface of the second wiring layer BLI2 may be exposed. However, the end portion of the second wiring layer BLI2 including the side surface thereof may be covered with the seventh insulating layer 128, and the material (e.g., titanium (Ti)) of the top surface of the second wiring layer BLI2 may be a suitable material having a strong etching resistance against the etchant used in the patterning process of the pixel electrode layer PCDL. Accordingly, damage to the second wiring layer BLI2 may be reduced or prevented without forming a separate protective layer on the second wiring layer BLI2. Therefore, according to some embodiments, the manufacturing process of the display device 1 may be simplified, and the reliability of the display device 1 may be ensured.

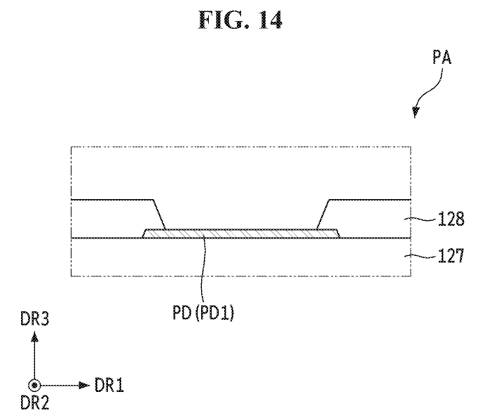

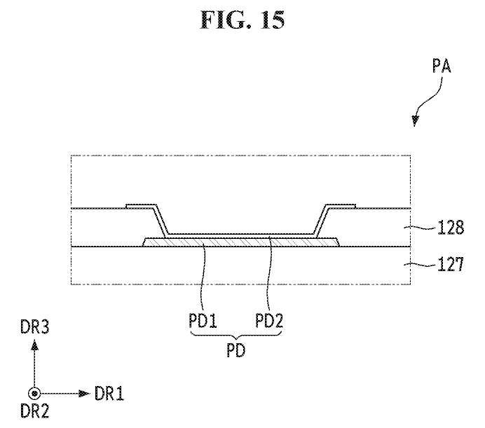

FIG. 14 is a cross-sectional view illustrating a pad according to an embodiment. FIG. 15 is a cross-sectional view illustrating a pad according to an embodiment. For example, FIGS. 14 and 15 show different embodiments of a cross-section of the pad PD that may be arranged in the pad area PA of FIG. 2.

The pad PD of FIG. 14 or FIG. 15 may be located at one edge of the sub-region SBA of FIGS. 1 and 2 to be electrically connected to the circuit board 300, or may be located below the display driving circuit 250 to be electrically connected to the display driving circuit 250. In an embodiment, the pads PD of the display panel 100 (e.g., the pads PD each electrically connected to the circuit board 300 or the display driving circuit 250) may be formed concurrently (e.g., simultaneously or substantially simultaneously) with each other using the same conductive material, and may have the same or substantially the same (or similar) cross-sectional structure.

Referring to FIGS. 14 and 15 in addition to FIGS. 1 to 13, the pad PD may include a first pad layer PD1, and may further include a second pad layer PD2 optionally. For example, the pad PD may include the first pad layer PD1 as shown in FIG. 14, or may include the first pad layer PD1 and the second pad layer PD2 located on the first pad layer PD1 as shown in FIG. 15.

In an embodiment, the first pad layer PD1 may be formed as a pattern included in the backplane layer 120 of the display panel 100. For example, the first pad layer PD1 may be formed as a pattern of the second source-drain conductive layer SCDL2, and may be formed as a single-layer or multi-layered pattern including a low-resistance material. For example, the first pad layer PD1 may be formed in a three-layered structure (Ti/Al/Ti) of titanium (Ti), aluminum (Al), and titanium (Ti). Accordingly, the resistance of the pad PD may be reduced.

The patterns of the conductive layer including the first pad layer PD1, for example, such as the second source-drain conductive layer SCDL2, may be formed before the patterns of the pixel electrode layer PCDL. Before the process for forming the patterns of the pixel electrode layer PCDL is performed, the seventh insulating layer 128 may be opened to expose a part of the first pad layer PD1. Thus, a part of the top surface of the first pad layer PD1 may be exposed. However, the end portion of the first pad layer PD1 including the side surface thereof may be covered with the seventh insulating layer 128, and the material included in the top surface of the first pad layer PD1 (e.g., titanium (Ti)) may be a suitable material with a strong etching resistance against the etchant used in the patterning process of the pixel electrode layer PCDL. Accordingly, damage to the first pad layer PD1 may be reduced or prevented without forming a separate protective layer on the first pad layer PD1. Therefore, according to some embodiments, the manufacturing process of the display device 1 may be simplified, and the reliability of the display device 1 may be ensured.

In an embodiment, the second pad layer PD2 may be formed concurrently (e.g., simultaneously or substantially simultaneously) with some of the patterns included in the light emitting element layer 130 of the display panel 100. For example, the second pad layer PD2 may be formed concurrently (e.g., simultaneously or substantially simultaneously) with the connection electrodes BE, and the second pad layer PD2 and the connection electrodes BE may include the same conductive material as each other. For example, the second pad layer PD2 may include a transparent conductive oxide (TCO), such as indium-tin oxide (ITO) or indium-zinc oxide (IZO). By covering the first pad layer PD1 with the second pad layer PD2, the reliability of the pad PD may be further improved.

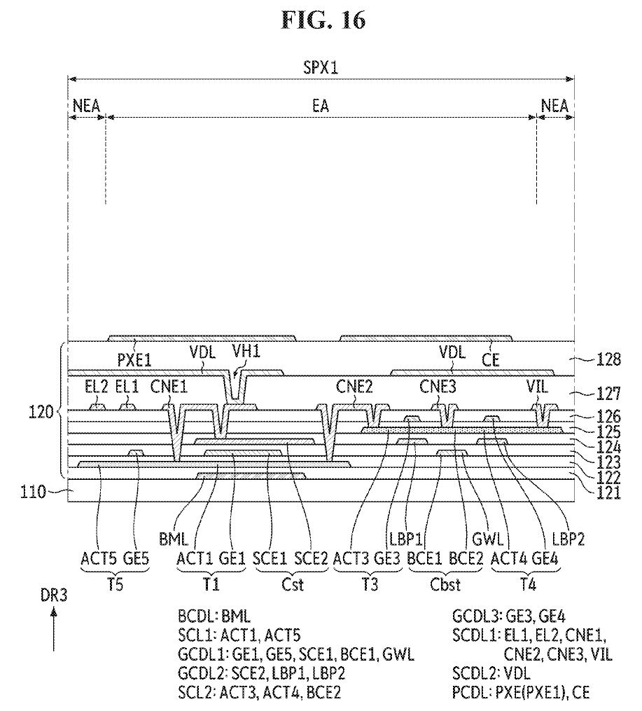

FIGS. 16 through 19 are cross-sectional views showing a method for manufacturing a display device according to an embodiment. For example, FIGS. 16 to 19 sequentially show manufacturing processes for forming the light emitting element layer 130 among manufacturing processes for manufacturing the display panel 100 according to the embodiment illustrated in FIG. 8.

Referring to FIG. 16 in addition to FIGS. 8 to 10, the pixel electrode layer PCDL may be formed on the substrate 110. For example, the backplane layer 120 may be formed on the substrate 110, and the pixel electrode layer PCDL including the pixel electrodes PXE and the common electrode CE of the sub-pixels SPX may be formed on the backplane layer 120.

In an embodiment, the backplane layer 120 may include the second wiring layer BLI2 of the power bus line BLI shown in FIG. 13, and the first pad layer PD1 of the pad PD shown in FIGS. 14 and 15. In this case, in the process of forming the backplane layer 120, for example, such as the process of forming the second source- drain conductive layer SCDL2, the second wiring layer BLI2 of the power bus line BLI and the first pad layer PD1 of the pad PD may be formed.

The patterns of the pixel electrode layer PCDL may be formed as single-layer or multi-layered patterns using at least one conductive material. For example, a single-layer or multi-layered conductive film may be (e.g., entirely) formed on the backplane layer 120 using at least one conductive material containing a conductive material suitable for forming the reflective layer RFL included in the patterns of the pixel electrode layer PCDL, and then the conductive film may be formed as the patterns of the pixel electrode layer PCDL by performing a patterning process including an etching process of the conductive film. For example, by etching the conductive film, the pixel electrode PXE and the common electrode CE may be formed to be spaced apart from each other in the emission area EA of each sub-pixel SPX. Each of the pixel electrode PXE and the common electrode CE may be formed as a reflective electrode including the reflective layer RFL.

For example, indium-tin oxide (ITO), silver (Ag), and indium-tin oxide (ITO) may be sequentially deposited to form a conductive film having a three-layered structure (ITO/Ag/ITO). Thereafter, the conductive film is etched using a mask to form the pixel electrodes PXE and the common electrode CE of the sub-pixels SPX. Accordingly, each of the pixel electrodes PXE and the common electrode CE of the sub-pixels SPX may be formed as a conductive pattern having a three-layered structure (ITO/Ag/ITO) of indium-tin oxide (ITO), silver (Ag), and indium-tin oxide (ITO).

As each of the patterns of the pixel electrode layer PCDL includes the reflective layer RFL, each of the pixel electrodes PXE and the common electrode CE may function as a reflective plate. For example, each of the pixel electrodes PXE and the common electrode CE may be formed as an electrode integrated with a reflective plate. Accordingly, the light efficiency of the sub-pixels SPX may be improved without forming a separate reflective plate. According to an embodiment, the light efficiency of the sub-pixels SPX and the display device 1 including the same may be improved, and the manufacturing process of the display device 1 may be simplified. For example, by forming each of the pixel electrodes PXE and the common electrode CE as an electrode integrated with a reflective plate, the number of mask processes performed during the manufacturing process of the display panel 100 may be reduced or minimized, and the manufacturing efficiency of the display panel 100 may be increased.

In an embodiment, the patterns of the pixel electrode layer PCDL may include the first wiring layer BLI1 of the power bus line BLI. The first wiring layer BLI1 of the power bus line BLI may be formed concurrently (e.g., simultaneously or substantially simultaneously) with the pixel electrodes PXE and the common electrode CE. For example, the first wiring layer BLI1 of the power bus line BLI and the common electrode CE may be formed as one body to constitute a single or substantially a single conductive pattern.

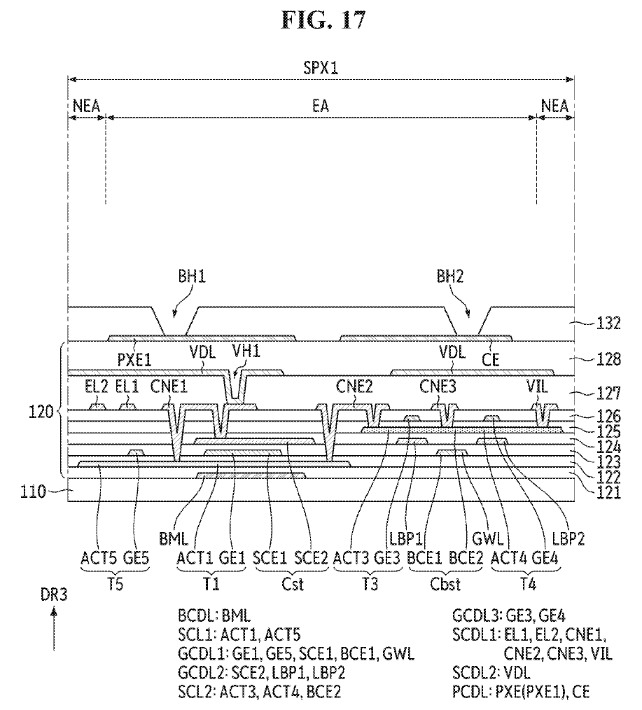

Referring to FIG. 17, the eighth insulating layer 132 (e.g., a tackifying layer) may be formed on the pixel electrode layer PCDL. For example, after the eighth insulating layer 132 is entirely formed in the display area DA using at least one insulating material (e.g., an organic insulating material), a part of the eighth insulating layer 132 may be etched or removed to form the first connection hole BH1 and the second connection hole BH2 of each sub-pixel SPX. As another example, in each of the sub-pixels SPX, the eighth insulating layer 132 may be left in only one part including the light emitting element area, and the eighth insulating layer 132 may be etched or removed from another part. Accordingly, the eighth insulating layer 132 may be formed to cover parts of the pixel electrode PXE and the common electrode CE, and may expose the other parts of the pixel electrode PXE and the common electrode CE.

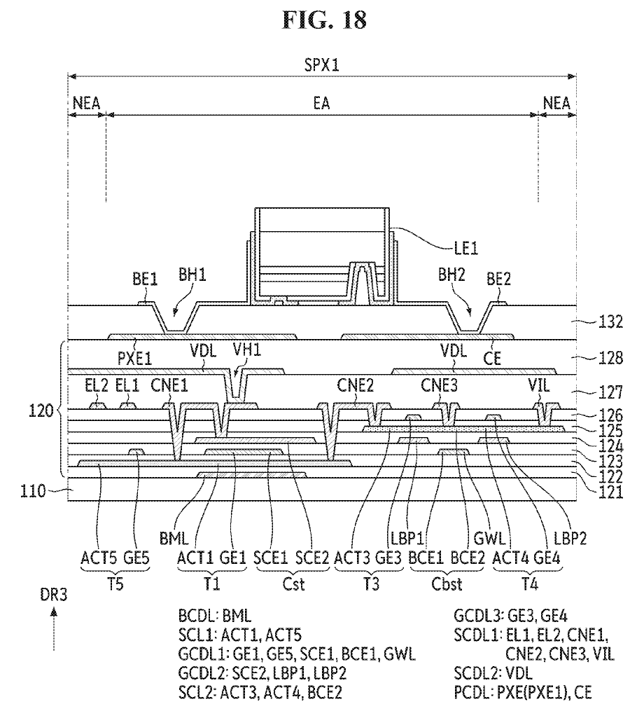

Referring to FIG. 18, the light emitting element LE of each sub-pixel SPX may be arranged on the eighth insulating layer 132. In an embodiment, the light emitting elements LE may be grown and formed on a semiconductor substrate, such as a silicon substrate or a sapphire substrate, and then transferred onto the pixel electrodes PXE and the common electrode CE of the display panel 100.

Thereafter, the first connection electrode BE1 and the second connection electrode BE2 of each sub-pixel SPX may be formed. For example, the first connection electrode BE1 may be formed on the pixel electrode PXE and the eighth insulating layer 132, and the second connection electrode BE2 may be formed on the common electrode CE and the eighth insulating layer 132. In an embodiment, the first connection electrode BE1 and the second connection electrode BE2 may be formed using a transparent conductive oxide, and may be formed by a sputtering method or other suitable methods.

In an embodiment, the pad PD may further include the second pad layer PD2 as shown in FIG. 15. The second pad layer PD2 may be formed concurrently (e.g., simultaneously or substantially simultaneously) with the first and second connection electrodes BE1 and BE2 of the sub-pixels SPX. For example, the first and second connection electrodes BE1 and BE2 of the sub-pixels SPX and the second pad layers PD2 of the pads PD may be formed using a transparent conductive oxide.

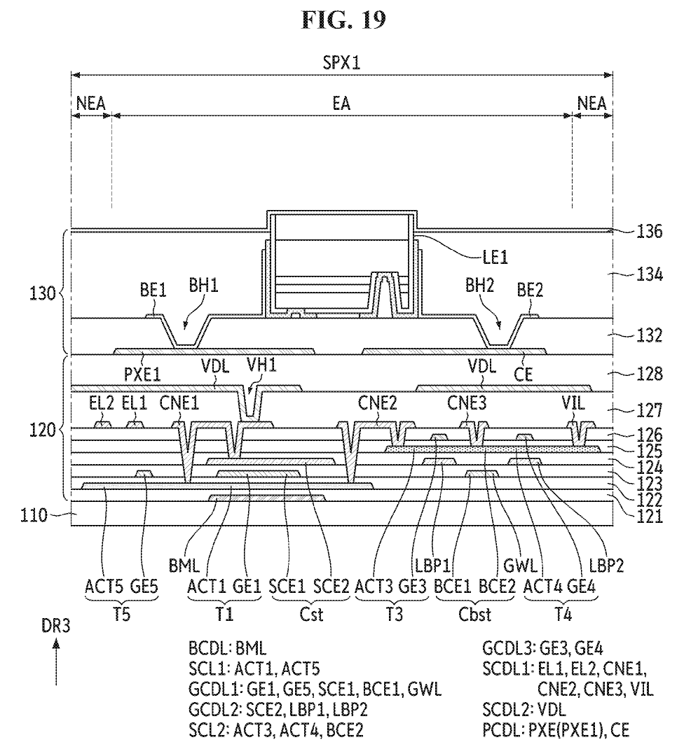

Referring to FIG. 19, the ninth insulating layer 134 may be formed on the light emitting element LE, the first connection electrode BE1, and the second connection electrode BE2 of each sub-pixel SPX. In an embodiment, the ninth insulating layer 134 may be formed to have a height less than or equal to the height of the light emitting element LE using at least one organic insulating material, but the present disclosure is not limited thereto. The ninth insulating layer 134 may alleviate or eliminate stepped portions that may be caused by the light emitting elements LE.

Thereafter, the first capping layer 136 may be formed on the ninth insulating layer 134. In an embodiment, the first capping layer 136 may be formed as a thin film with a small thickness using at least one inorganic insulating material. For example, the first capping layer 136 may have a suitable material and thickness for protecting the patterns and/or the light emitting elements LE arranged on the light emitting element layer 130.

Through the aforementioned process with reference to FIGS. 16 to 19, the light emitting element layer 130 of the display panel 100 according to an embodiment may be formed. Thereafter, the optical layer 140 of FIG. 8 may be formed on the light emitting element layer 130. Accordingly, the display panel 100 illustrated in FIG. 8 may be manufactured.

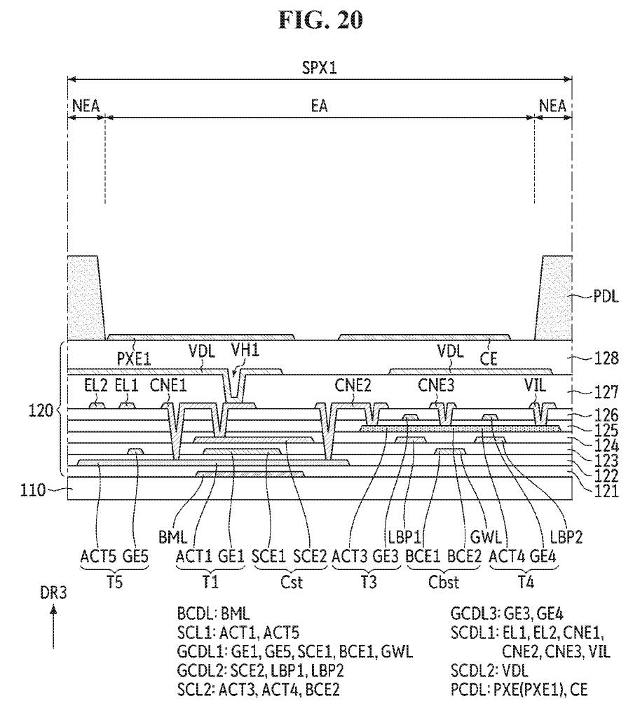

FIGS. 20 through 22 are cross-sectional views showing a method for manufacturing a display device according to an embodiment. For example, FIGS. 20 to 22 sequentially show manufacturing processes for forming the light emitting element layer 130 among manufacturing processes for manufacturing the display panel 100 according to the embodiment illustrated in FIG. 11.

Referring to FIG. 20 in addition to FIG. 11, the pixel electrode layer PCDL and the pixel defining layer PDL may be formed on the substrate 110. For example, the backplane layer 120 may be formed on the substrate 110, and the pixel electrode layer PCDL and the pixel defining layer PDL may be formed on the backplane layer 120.

In an embodiment, after forming the pixel electrode layer PCDL on the backplane layer 120, the pixel defining layer PDL may be formed. However, the present disclosure is not limited thereto. For example, in another embodiment, the pixel electrode layer PCDL may be formed after forming the pixel defining layer PDL on the backplane layer 120.

The patterns of the pixel electrode layer PCDL (e.g., the pixel electrodes PXE, the common electrode CE, and the first wiring layer BLI1 of the power bus line BLI) may be formed as single-layer or multi-layered patterns using at least one conductive material. Because the method of forming the patterns of the pixel electrode layer PCDL has been described above with reference to FIG. 16, redundant description thereof may not be repeated.

The pixel defining layer PDL may be formed as a single-layer or multi-layered pattern using at least one insulating material (e.g., an organic insulating material). The pixel defining layer PDL may be formed to surround (e.g., around a periphery of) each emission area EA where the pixel electrode PXE, the common electrode CE, and the light emitting element LE are to be arranged. For example, the pixel defining layer PDL may be formed in the non-emission area NEA by performing an insulating film forming process using the materials described above as a material of the pixel defining layer PDL and a patterning process.

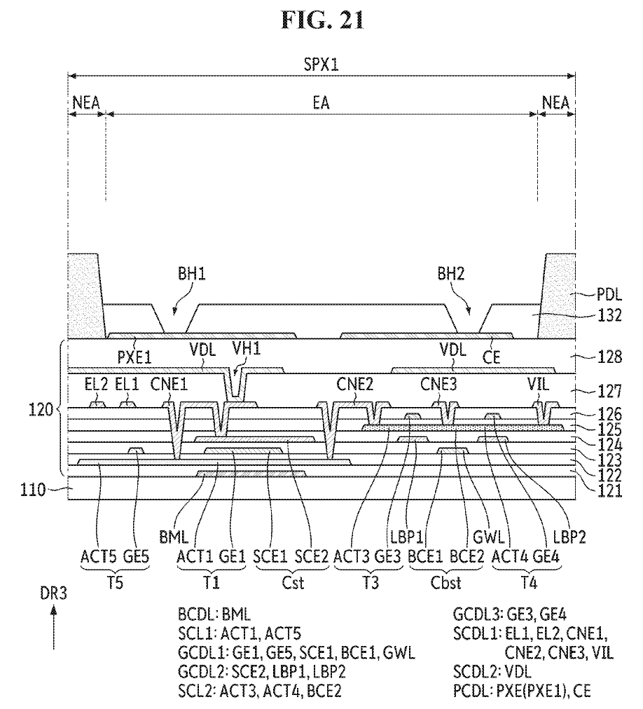

Referring to FIG. 21, the eighth insulating layer 132 (e.g., a tackifying layer) may be formed on the pixel electrode layer PCDL. Because the method of forming the eighth insulating layer 132 has been described above with reference to FIG. 17, redundant description thereof may not be repeated. In an embodiment, the eighth insulating layer 132 may be formed in the emission area EA of each sub-pixel SPX while being surrounded (e.g., around a periphery thereof) by the pixel defining layer PDL. In an embodiment, the eighth insulating layer 132 may partially cover the side surface of the pixel defining layer PDL, but the present disclosure is not limited thereto.

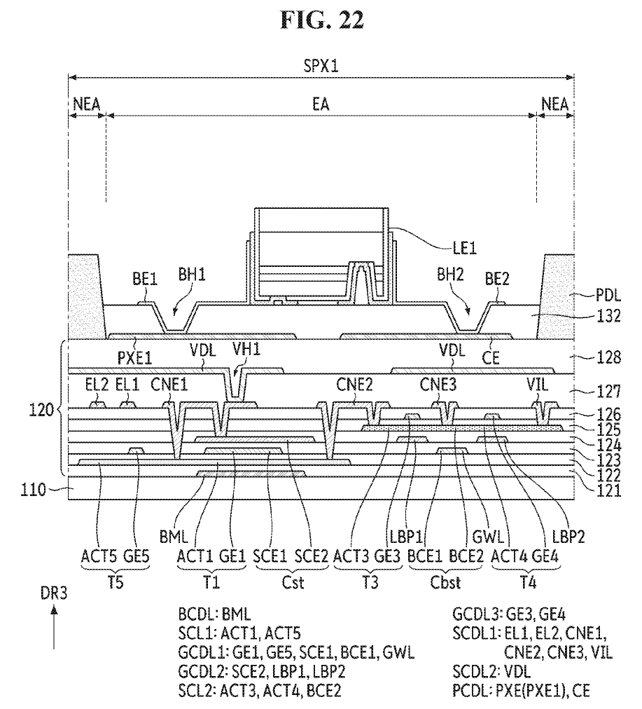

Referring to FIG. 22, after arranging the light emitting element LE of each sub-pixel SPX on the eighth insulating layer 132, the first connection electrode BE1 and the second connection electrode BE2 of each sub-pixel SPX may be formed. Because the method of arranging the light emitting element LE of each sub-pixel SPX and the method of forming the first connection electrode BE1 and the second connection electrode BE2 of each sub-pixel SPX have been described above with reference to FIG. 18, redundant description thereof may not be repeated.

Thereafter, the ninth insulating layer 134 and the first capping layer 136 of FIG. 11 may be formed on the light emitting element LE, the first connection electrode BE1, and the second connection electrode BE2 of each sub-pixel SPX. Because the method of forming the ninth insulating layer 134 and the first capping layer 136 has been described above with reference to FIG. 19, redundant description thereof may not be repeated.

The light emitting element layer 130 of the display panel 100 according to an embodiment may be formed through the aforementioned process. Thereafter, the optical layer 140 of FIG. 11 may be formed on the light emitting element layer 130. Accordingly, the display panel 100 illustrated in FIG. 11 may be manufactured.

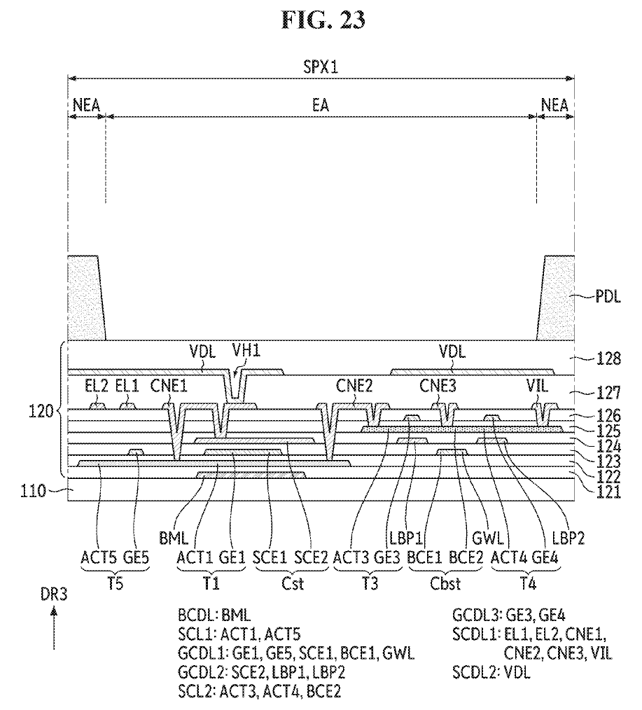

FIGS. 23 through 26 are cross-sectional views showing a method for manufacturing a display device according to an embodiment. For example, FIGS. 23 to 26 sequentially show manufacturing processes for forming the light emitting element layer 130 among manufacturing processes for manufacturing the display panel 100 according to the embodiment illustrated in FIG. 12.

Referring to FIG. 23 in addition to FIG. 12, the pixel defining layer PDL may be formed on the substrate 110. For example, the backplane layer 120 may be formed on the substrate 110, and the pixel defining layer PDL may be formed on the backplane layer 120. In an embodiment, the pixel defining layer PDL may be formed before the forming of the pixel electrode layer PCDL described above with reference to FIG. 12. Because the method of forming the pixel defining layer PDL has been described above with reference to FIG. 20, redundant description thereof may not be repeated.

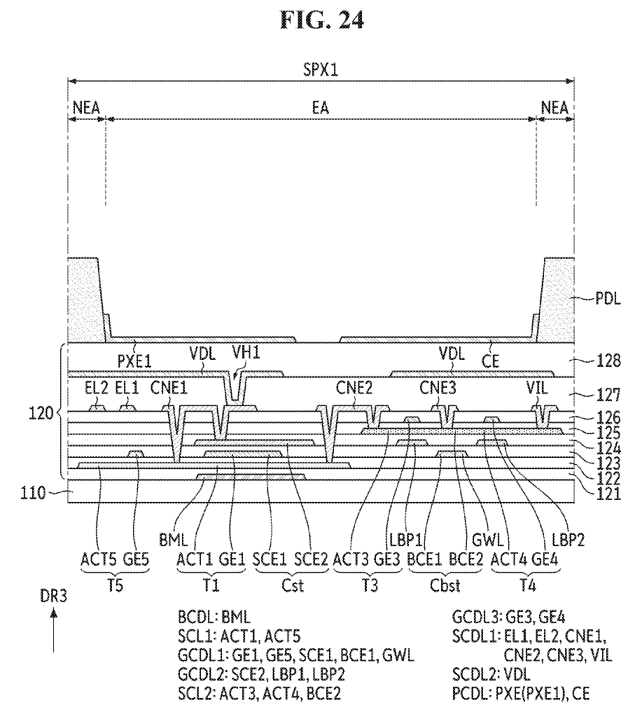

Referring to FIG. 24, the pixel electrode layer PCDL may be formed on the backplane layer 120 and the pixel defining layer PDL. The patterns of the pixel electrode layer PCDL (e.g., the pixel electrodes PXE, the common electrode CE, and the first wiring layer BLI1 of the power bus line BLI) may be formed as single-layer or multi-layered patterns using at least one conductive material. Because the method of forming patterns of the pixel electrode layer PCDL has been described above with reference to FIG. 16, redundant description thereof may not be repeated.

In an embodiment, the pixel electrodes PXE and the common electrode CE may extend to the non-emission area NEA (e.g., the boundary area between the emission area EA and the non-emission area NEA) to be formed on a part of the pixel defining layer PDL. For example, the edge portions of the pixel electrodes PXE and the common electrode CE may be formed on the side surface of the pixel defining layer PDL. In an embodiment, the edge portions of the pixel electrodes PXE and the common electrode CE may be formed to have a height lower than the height of the pixel defining layer PDL to cover a part of the side surface of the pixel defining layer PDL. However, the present disclosure is not limited thereto. For example, in another embodiment, the edge portions of the pixel electrodes PXE and the common electrode CE may entirely cover the side surface of the pixel defining layer PDL.

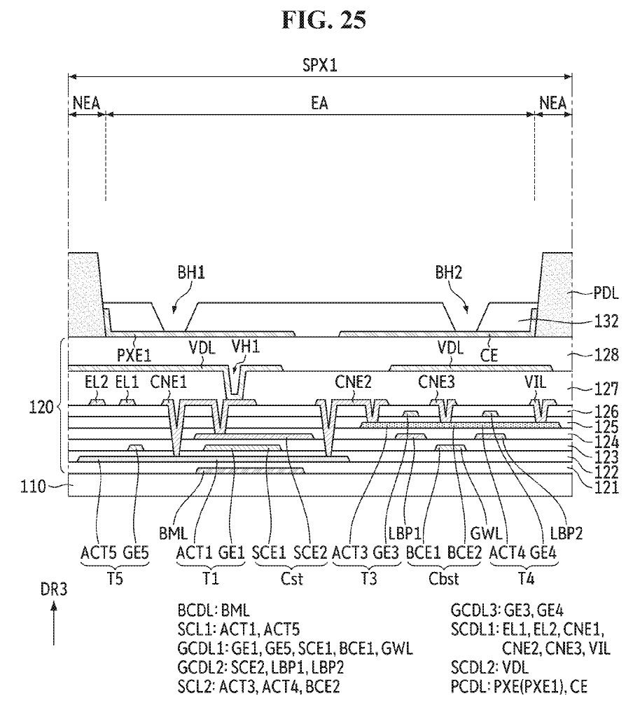

Referring to FIG. 25, the eighth insulating layer 132 (e.g., a tackifying layer) may be formed on the pixel electrode layer PCDL. Because the method of forming the eighth insulating layer 132 has been described above with reference to FIGS. 17 and 21, redundant description thereof may not be repeated.

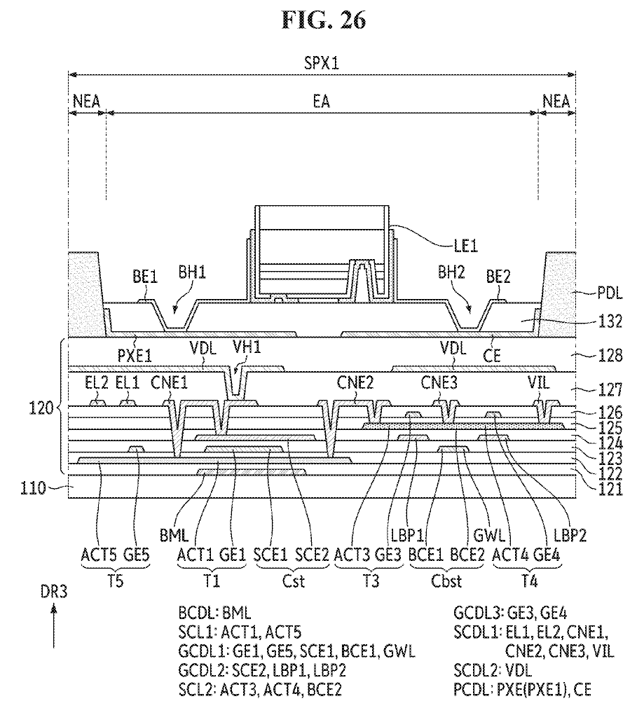

Referring to FIG. 26, after arranging the light emitting element LE of each sub-pixel SPX on the eighth insulating layer 132, the first connection electrode BE1 and the second connection electrode BE2 of each sub-pixel SPX may be formed. Because the method of arranging the light emitting element LE of each sub-pixel SPX and the method of forming the first connection electrode BE1 and the second connection electrode BE2 of each sub-pixel SPX have been described above with reference to FIG. 18, redundant description thereof may not be repeated.

Thereafter, the ninth insulating layer 134 and the first capping layer 136 of FIG. 12 may be formed on the light emitting element LE, the first connection electrode BE1, and the second connection electrode BE2 of each sub-pixel SPX. Because the method of forming the ninth insulating layer 134 and the first capping layer 136 has been described above with reference to FIG. 19, redundant description thereof may not be repeated.

The light emitting element layer 130 of the display panel 100 according to an embodiment may be formed through the aforementioned process. Thereafter, the optical layer 140 of FIG. 12 may be formed on the light emitting element layer 130. Accordingly, the display panel 100 illustrated in FIG. 12 may be manufactured.

The display device 1 according to at least one of the above-described embodiments may be applied to various suitable electronic devices. The electronic device according to an embodiment may include the above-described display device 1 (e.g., the display module including the display panel 100 according to at least one embodiment), and may further include other modules or devices having other additional functions in addition to the display device 1.

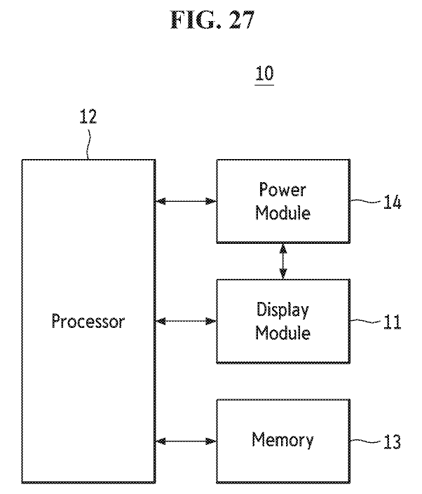

FIG. 27 is a block diagram of an electronic device according to an embodiment. Referring to FIG. 27, an electronic device 10 according to an embodiment may include a display module (e.g., a display or a touch-display) 11, a processor 12, a memory 13, and a power module (e.g., a power supply) 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module 11. For example, the memory 15 may store an image data signal and/or an input control signal.

The processor 12 may control the display module 11 using information stored in the memory 15. The processor 12 may transmit the image data signal and/or the input control signal stored in the memory 15 to the display module 11. For example, when the processor 12 executes an application stored in the memory 15, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the electronic device 10 described above may be included in the display device 1 according to the embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

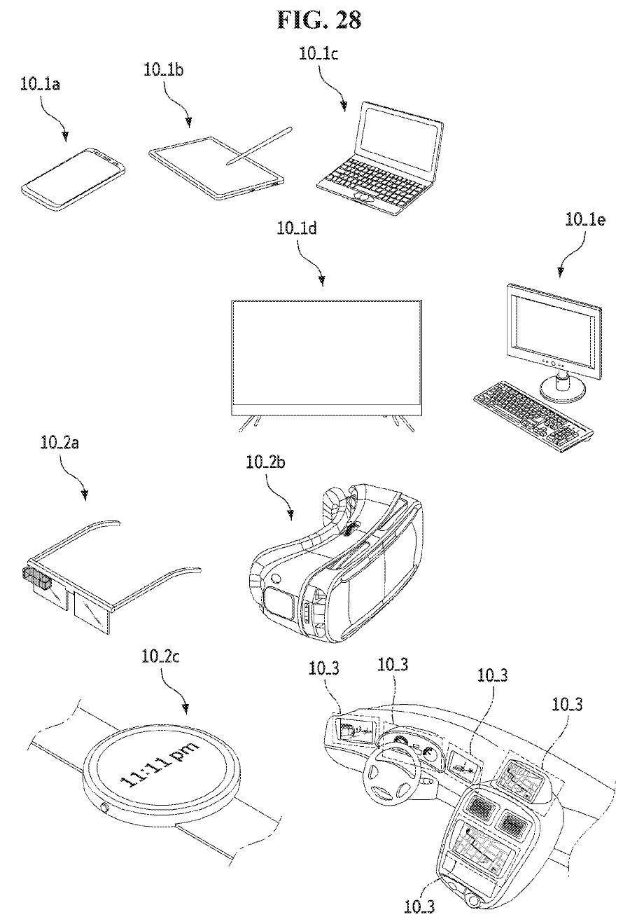

FIG. 28 is schematic views of electronic devices according to various embodiments.

Referring to FIG. 28, various electronic devices to which the display device 1 according to embodiments is applied may include not only an image display electronic device such as a smartphone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, or a smart watch 10_2c, a vehicle electronic device 10_3 including a display module, such as a center fascia, and a dashboard of an automobile, a center information display (CID) placed on the dashboard, a room mirror display, and the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a pixel electrode and a common electrode spaced from each other on a substrate; and
a light emitting element located on the pixel electrode and the common electrode, and electrically connected between the pixel electrode and the common electrode,
wherein the pixel electrode and the common electrode respectively comprise reflective layers overlapping with different parts of the light emitting element from each other.

2. The display device of claim 1, further comprising a pixel defining layer surrounding around the light emitting element and spaced from the light emitting element.

3. The display device of claim 2, wherein edge portions of the pixel electrode and the common electrode are located on a side surface of the pixel defining layer.

4. The display device of claim 1, wherein each of the pixel electrode and the common electrode has a three-layered structure of indium-tin oxide (ITO), silver (Ag), and indium-tin oxide (ITO).

5. The display device of claim 1, further comprising:
an adhesive layer covering a part of the pixel electrode and a part of the common electrode, and comprising a portion overlapping with the light emitting element from under the light emitting element;
a first connection electrode located on the pixel electrode and the adhesive layer, and connecting a part of the light emitting element to the pixel electrode; and
a second connection electrode located on the common electrode and the adhesive layer, and connecting another part of the light emitting element to the common electrode.

6. The display device of claim 5, wherein the first connection electrode is in contact with one side surface of the light emitting element on a part of the pixel electrode and the adhesive layer, and is in contact with the pixel electrode on another part of the pixel electrode, and
the second connection electrode is in contact with another side surface of the light emitting element on a part of the common electrode and the adhesive layer, and is in contact with the common electrode on another part of the common electrode.

7. The display device of claim 1, further comprising a backplane layer located between the substrate and a pixel electrode layer comprising the pixel electrode and the common electrode,
wherein the backplane layer comprises a pixel circuit comprising a transistor, a connection pattern located below the pixel electrode and connecting the pixel electrode to the pixel circuit, and a power line electrically connected to the pixel circuit.

8. The display device of claim 7, further comprising a power bus line electrically connected to the common electrode, and comprising a first wiring layer extending from the common electrode.

9. The display device of claim 8, wherein the power bus line further comprises a second wiring layer located in the backplane layer, and electrically connected to the first wiring layer.

10. The display device of claim 9, further comprising a pad comprising a first pad layer located at a same layer as that of the second wiring layer, and comprising a same material as that of the second wiring layer.

11. The display device of claim 10, further comprising a first connection electrode connecting a part of the light emitting element to the pixel electrode, and a second connection electrode connecting another part of the light emitting element to the common electrode,
wherein the pad further comprises a second pad layer located on the first pad layer, and comprising a same conductive material as a conductive material in the first connection electrode and the second connection electrode.

12. The display device of claim 11, wherein the first connection electrode, the second connection electrode, and the second pad layer comprise a transparent conductive oxide.

13. A method for manufacturing a display device, comprising:
forming a pixel electrode and a common electrode on a substrate;
forming an adhesive layer covering a part of the pixel electrode and a part of the common electrode;
arranging a light emitting element on the adhesive layer; and
forming a first connection electrode connecting a part of the light emitting element to the pixel electrode on the pixel electrode and the adhesive layer, and forming a second connection electrode connecting another part of the light emitting element to the common electrode on the common electrode and the adhesive layer,
wherein each of the pixel electrode and the common electrode is formed as a reflective electrode comprising a reflective layer.

14. The method of claim 13, further comprising:
before the forming of the pixel electrode and the common electrode, forming a pixel defining layer surrounding around an emission area where the pixel electrode, the common electrode, and the light emitting element are to be arranged on the substrate,
wherein edge portions of the pixel electrode and the common electrode are formed on a side surface of the pixel defining layer.

15. The method of claim 13, further comprising:
before the arranging of the light emitting element after the forming of the pixel electrode and the common electrode, forming a pixel defining layer surrounding around an emission area where the pixel electrode and the common electrode are arranged on the substrate.

16. An electronic device comprising:
a display module comprising a display panel; and
a processor configured to transmit an image data signal to the display module,
wherein the display panel comprises:
a pixel electrode and a common electrode spaced from each other on a substrate; and
a light emitting element on the pixel electrode and the common electrode, and electrically connected between the pixel electrode and the common electrode,
wherein the pixel electrode and the common electrode respectively comprise reflective layers overlapping with different parts of the light emitting element from each other.

17. The electronic device of claim 16, wherein the display panel further comprises a pixel defining layer surrounding around the light emitting element and spaced from the light emitting element.

18. The electronic device of claim 17, wherein edge portions of the pixel electrode and the common electrode are located on a side surface of the pixel defining layer.

19. The electronic device of claim 16, wherein each of the pixel electrode and the common electrode has a three-layered structure of indium-tin oxide (ITO), silver (Ag), and indium-tin oxide (ITO).

20. The electronic device of claim 16, wherein the display panel further comprises:
an adhesive layer covering a part of the pixel electrode and a part of the common electrode, and comprising a portion overlapping with the light emitting element from under the light emitting element;
a first connection electrode located on the pixel electrode and the adhesive layer, and connecting a part of the light emitting element to the pixel electrode; and
a second connection electrode located on the common electrode and the adhesive layer, and connecting another part of the light emitting element to the common electrode.
